(19) United States
(12) Patent Application Publication
(10) Pub. No.: US 2025/0024686 A1
(43) Pub. Date: Jan. 16, 2025

(54) FERROELECTRIC SEMICONDUCTOR DEVICE INCLUDING MEMORY CELL HAVING A THREE-DIMENSIONAL STRUCTURE

(71) Applicant: SK hynix Inc., Icheon-si (KR)

(72) Inventors: Mir IM, Icheon-si (KR); Joong Sik KIM, Icheon-si (KR)

(21) Appl. No.: 18/584,199

(22) Filed: Feb. 22, 2024

(30) Foreign Application Priority Data
Jul. 14, 2023 (KR) 10-2023-0092069

(51) Int. Cl. H10B 51/30; H01L 29/78; H10B 51/10; H10B 51/20

(52) U.S. Cl. CPC H10B 51/30; H01L 29/78391; H10B 51/10; H10B 51/20

(57) ABSTRACT

A ferroelectric semiconductor device according to an embodiment includes a substrate, a channel layer disposed over the substrate to extend in a vertical direction substantially perpendicular to a surface of the substrate, an interfacial dielectric layer disposed on the channel layer, and a floating electrode layer disposed on the interfacial dielectric layer. The floating electrode layer includes first and second electrode portions respectively disposed on different portions of the interfacial dielectric layer. In addition, the ferroelectric semiconductor device includes a ferroelectric layer disposed on the first electrode portion of the floating electrode layer, a gate electrode layer disposed on the ferroelectric layer, and an insulation structure covering the second electrode portion of the floating electrode layer over the substrate.

### CROSS-REFERENCE TO RELATED APPLICATIONS

The present application claims priority under 35 U.S.C. § 119(a) to Korean Application No. 10-2023-0092069, filed in the Korean Intellectual Property Office on Jul. 14, 2023, which is incorporated herein by reference in its entirety.

### BACKGROUND

### 1. Technical Field

The present disclosure generally relates to a ferroelectric semiconductor device and, more particularly, to a ferroelectric semiconductor device including a memory cell having a three-dimensional structure.

### 2. Related Art

As design rules decrease and integration levels increase, research into nonvolatile memory devices utilizing a three-dimensional structure continues. Currently, a NAND flash memory device using a charge storage method employing a three-layer stack structure of a charge tunneling layer, a charge trap layer, and a charge barrier layer is widely applied.

Recently, non-volatile memory devices employing an operation method other than the charge storage method have been reported. As an example, a ferroelectric memory device using a ferroelectric layer as a gate dielectric layer of a field effect transistor is being researched. The ferroelectric memory device may use the mutually identified remanent polarization states of the ferroelectric layer to store signal information. In addition, a ferroelectric memory device can be effectively stacked in three dimensions, thereby improving the degree of integration of memory cells.

### SUMMARY

A ferroelectric semiconductor device according to an embodiment of the present disclosure may include a substrate, a channel layer disposed over the substrate to extend in a vertical direction substantially perpendicular to a surface of the substrate, an interfacial dielectric layer disposed on the channel layer, and a floating electrode layer disposed on the interfacial dielectric layer. The floating electrode layer may include first and second electrode portions respectively disposed on different portions of the interfacial dielectric layer. In addition, the ferroelectric semiconductor device may include a ferroelectric layer disposed on the first electrode portion of the floating electrode layer, a gate electrode layer disposed on the ferroelectric layer, and an insulation structure covering the second electrode portion of the floating electrode layer over the substrate.

A ferroelectric semiconductor device according to another embodiment of the present disclosure may include a substrate, a channel layer disposed over the substrate to extend in a vertical direction substantially perpendicular to a surface of the substrate, an interfacial dielectric layer disposed on a sidewall surface of the channel layer along the vertical direction, and a plurality of floating electrode layers disposed over the substrate to be spaced apart from each other along the vertical direction. Each of the floating electrode layers may include first and second electrode portions disposed on a plane substantially parallel to the surface of the substrate. In addition, the ferroelectric semiconductor device may include a plurality of ferroelectric layers disposed to respectively contact the first electrode portions of the plurality of floating electrode layers, a plurality of gate electrode layers disposed to be adjacent to the plurality of ferroelectric layers, and an insulation structure covering the second electrode portions of each of the plurality of floating electrode layers over the substrate.

A ferroelectric semiconductor device according to another embodiment of the present disclosure may include a substrate, and memory cell structures disposed along first and second directions that are substantially parallel to a surface of the substrate. Each of the memory cell structures may include a channel layer disposed over the substrate to extend in a vertical direction substantially perpendicular to the surface of the substrate, an interfacial dielectric layer disposed on the channel layer, a floating electrode layer disposed on the interfacial dielectric layer. The floating electrode layer may include first and second electrode portions respectively disposed on different portions of the interfacial dielectric layer. In addition, the ferroelectric semiconductor device may include a ferroelectric layer disposed on the first electrode portion of the floating electrode layer, a gate electrode layer disposed on the ferroelectric layer, and an insulation structure covering the second electrode portion of the floating electrode layer over the substrate.

### BRIEF DESCRIPTION OF THE DRAWINGS

FIG. 1 is a circuit diagram schematically illustrating a ferroelectric semiconductor device according to an embodiment of the present disclosure.

FIG. 2A is a plan view schematically illustrating a ferroelectric semiconductor device according to an embodiment of the present disclosure.

FIG. 2B is a cross-sectional view of a ferroelectric semiconductor device shown in FIG. 2A taken along a line I-I′.

FIG. 2C is a cross-sectional view of a ferroelectric semiconductor device shown in FIG. 2A taken along a line II-II′.

FIG. 2D is a view of a ferroelectric semiconductor device of FIG. 2B taken along a line III-III′ or a ferroelectric semiconductor device of FIG. 2C taken along a line IV-IV′, and shown on an x-y plane.

FIG. 2E is a view of a ferroelectric semiconductor device of FIG. 2B taken along a line V-V′ or a ferroelectric semiconductor device of FIG. 2C taken along a line VI-VI′, and shown on an x-y plane.

FIG. 2F is a view of a ferroelectric semiconductor device of FIG. 2B taken along a line VII-VII′ or the ferroelectric semiconductor device of FIG. 2C taken along a line VIII-VIII′, and shown on an x-y plane.

FIG. 3A is a view schematically illustrating an operation of a memory cell structure according to an embodiment of the present disclosure.

FIG. 3B is a circuit diagram of a ferroelectric semiconductor device of FIG. 3A.

FIGS. 4A to 15A are plan views schematically illustrating a method of manufacturing a ferroelectric semiconductor device according to an embodiment of the present disclosure.

FIGS. 4B to 15B are cross-sectional views corresponding to a semiconductor stack structures of FIGS. 4A to 15A taken along line A-A′.

FIG. 14C and FIG. 15C are cross-sectional views corresponding to a semiconductor stack structure of FIG. 14A and FIG. 15A taken along line B-B′.

FIGS. 16A and 16B are cross-sectional views schematically illustrating a ferroelectric semiconductor device according to another embodiment of the present disclosure.

FIGS. 17A and 17B are cross-sectional views schematically illustrating a ferroelectric semiconductor device according to further another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, in describing a method or a manufacturing method, each process constituting the method may proceed in a different order from the specified order unless a specific order is clearly described in context. That is, each process may proceed in the same order as specified, may proceed substantially concurrently, or may proceed in the opposite order.

Embodiments of the present disclosure may be described through drawings using the x-y-z coordinate system. The x-direction referred to in this specification may mean a direction parallel to the x-axis. Similarly, the y-direction and the z-direction may refer to directions parallel to the y-axis and z-axis, respectively.

In an embodiment of the present disclosure, a ferroelectric semiconductor device including a ferroelectric memory cell may be provided. The ferroelectric memory cell may be implemented as a field effect transistor using a ferroelectric layer as a gate dielectric layer. The ferroelectric memory cell may non-volatilely store at least two remanent polarization states formed in the ferroelectric layer as signal information. The ferroelectric semiconductor device may read signal information stored in the ferroelectric memory cell by using a characteristic in which a threshold voltage of the field effect transistor changes according to the remanent polarization. The ferroelectric semiconductor device may include memory cells stacked three-dimensionally on a substrate.

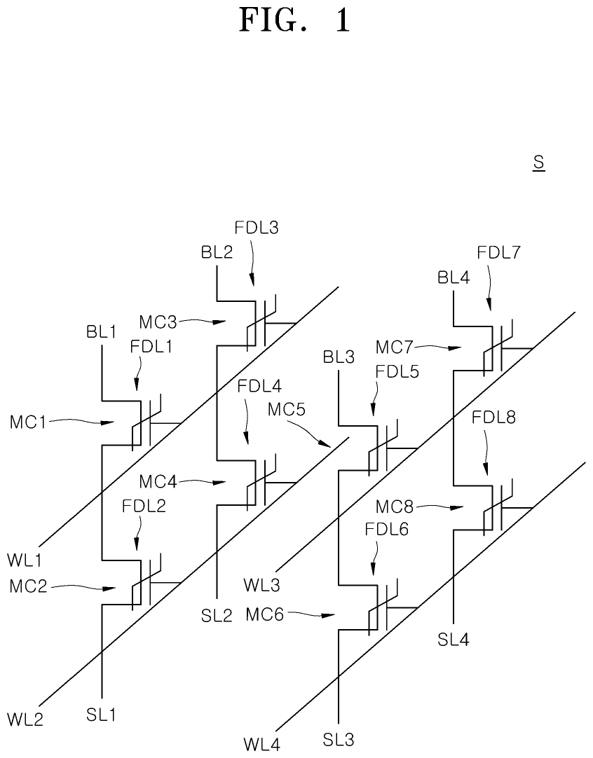

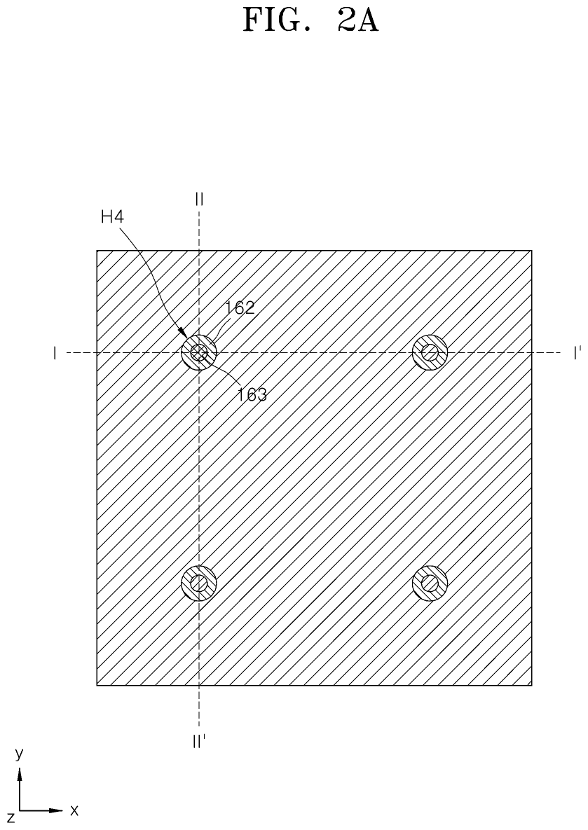

FIG. 1 is a circuit diagram schematically illustrating a ferroelectric semiconductor device according to an embodiment of the present disclosure. Referring to FIG. 1, a ferroelectric semiconductor device S may include a plurality of ferroelectric memory cells each having a shape of a field effect transistor.

In an embodiment, first and second ferroelectric memory cells MC1 and MC2, which are serially connected to each, other may be disposed between a first bit line BL1 and a first source line SL1. The first and second ferroelectric memory cells MC1 and MC2 may include first and second ferroelectric layers FDL1 and FDL2, respectively, as signal storage layers. In addition, third and fourth ferroelectric memory cells MC3 and MC4, which are serially connected to each other, may be disposed between a second bit line BL2 and a second source line SL2. The third and fourth ferroelectric memory cells MC3 and MC4 may include third and fourth ferroelectric layers FDL3 and FDL4, respectively, as signal storage layers. The first and third ferroelectric memory cells MC1 and MC3 may share a first word line WL1, and the second and fourth ferroelectric memory cells MC2 and MC4 may share a second word line WL2.

Similarly, fifth and sixth ferroelectric memory cells MC5 and MC6, which are serially connected to each other, may be disposed between a third bit line BL3 and a third source line SL3. The fifth and sixth ferroelectric memory cells MC5 and MC6 may include fifth and sixth ferroelectric layers FDL5 and FDL6, respectively, as signal storage layers. In addition, seventh and eighth ferroelectric memory cells MC7 and MC8, which are serially connected to each other, may be disposed between a fourth bit line BL4 and a fourth source line SL4. The seventh and eighth ferroelectric memory cells MC7 and MC8 may include seventh and eighth ferroelectric layers FDL7 and FDL8, respectively, as signal storage layers. In this case, the fifth and seventh ferroelectric memory cells MC5 and MC7 may share a third first word line WL3, and the sixth and eighth ferroelectric memory cells MC6 and MC8 may share a fourth word line WL4.

In FIG. 1, two ferroelectric memory cells are disposed between each of the first to fourth bit lines BL1, BL2, BL3, BL4 and each of corresponding first to fourth source lines SL1, SL2, SL3, SL4. Embodiments of the present disclosure, however, are not limited thereto, and various numbers of ferroelectric memory cells may be utilized and similarly disposed. In addition, the numbers of the bit lines and source lines are not limited to four, and various numbers are possible.

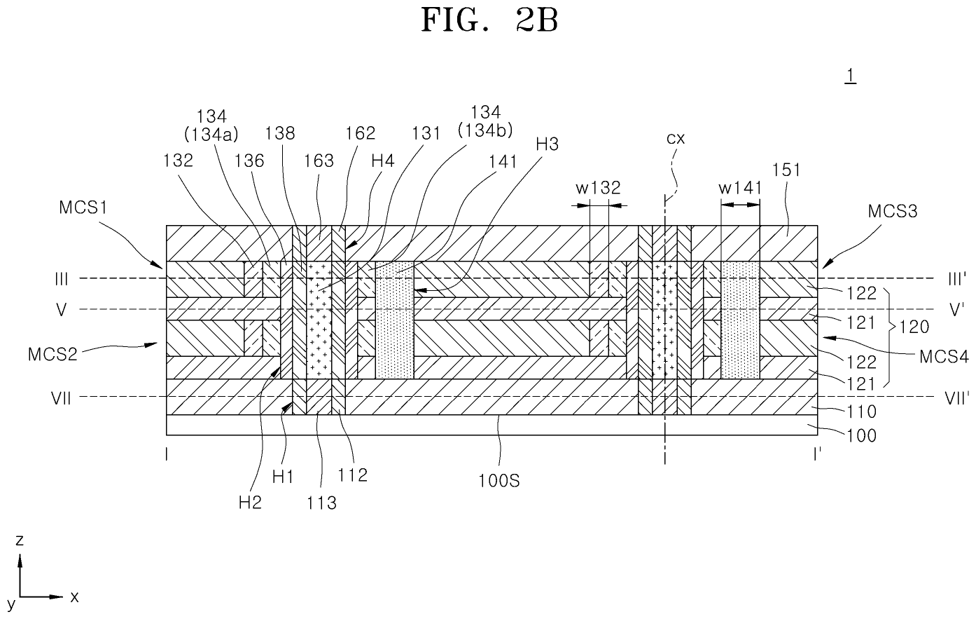

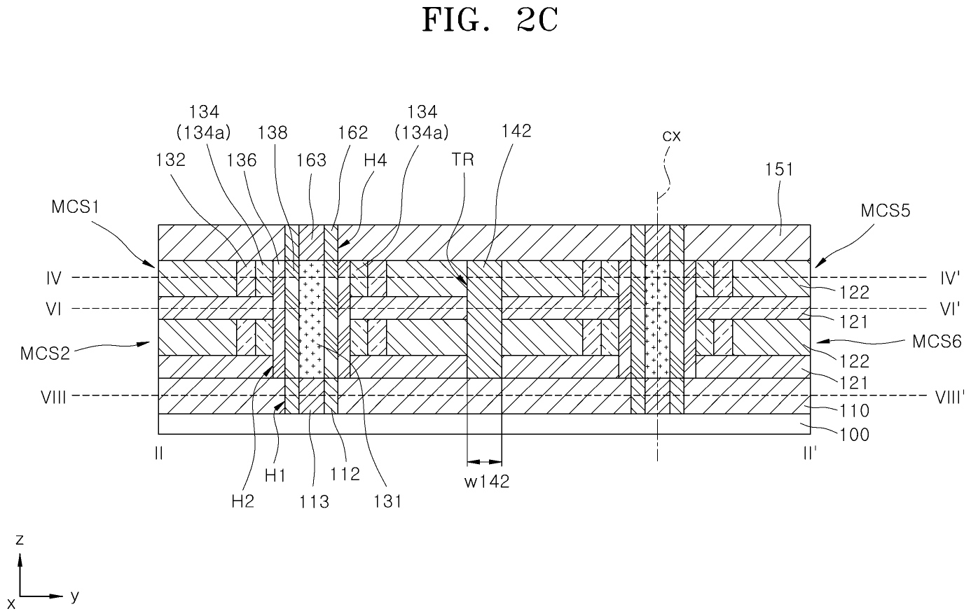

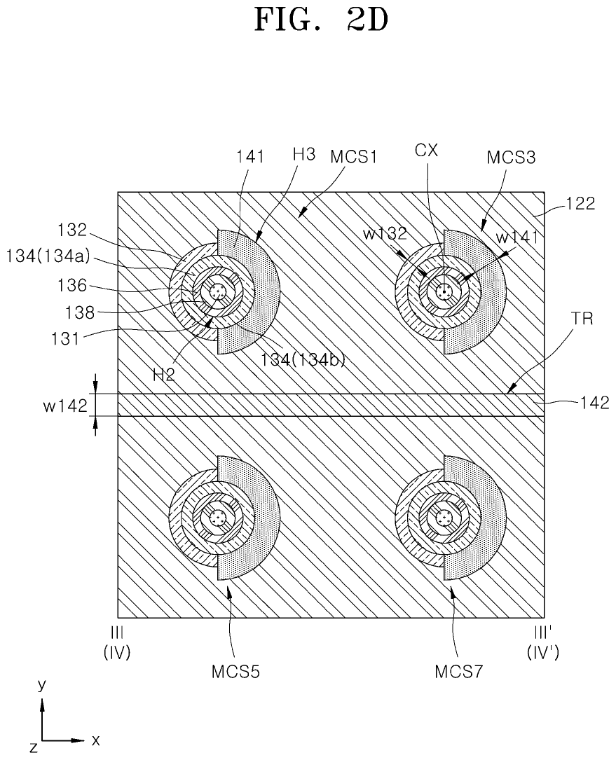

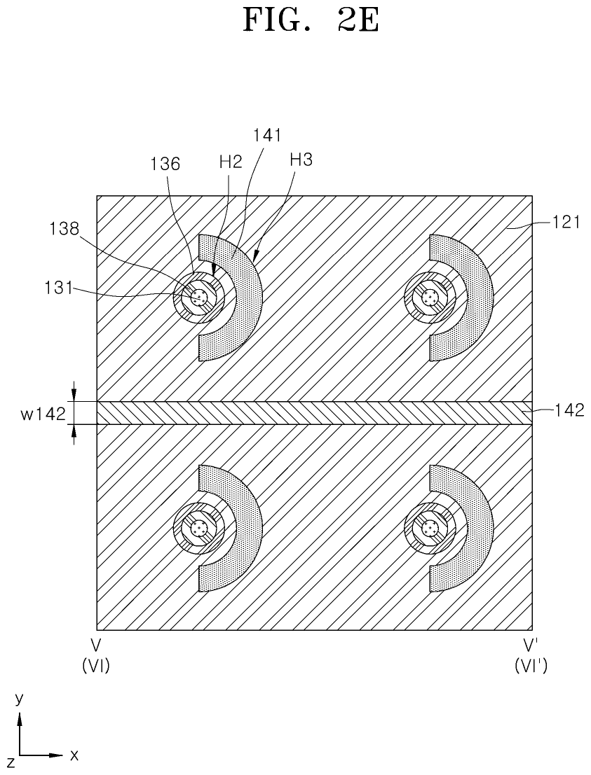

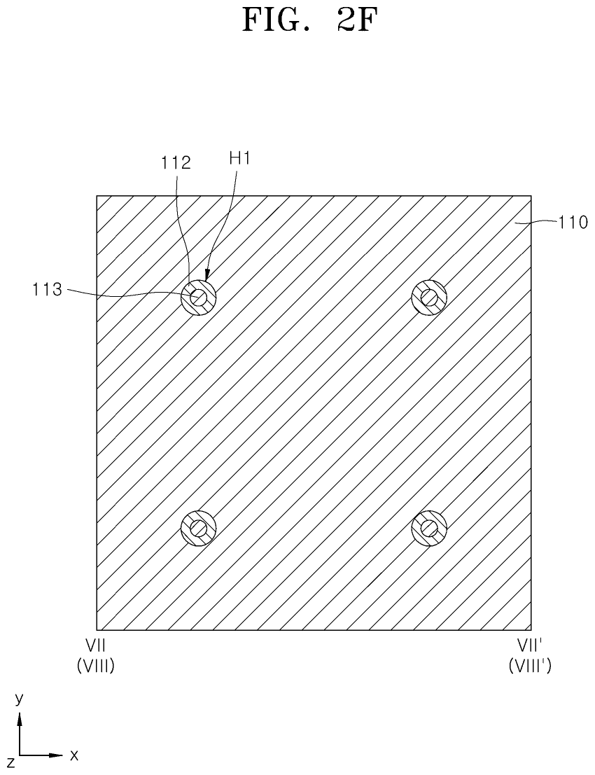

FIG. 2A is a plan view schematically illustrating a ferroelectric semiconductor device according to an embodiment of the present disclosure. FIG. 2B is a cross-sectional view of a ferroelectric semiconductor device shown in FIG. 2A taken along a line I-I′. FIG. 2C is a cross-sectional view of a ferroelectric semiconductor device shown in FIG. 2A taken along a line II-II′. FIG. 2D is a view of a ferroelectric semiconductor device of FIG. 2B taken along a line III-III′ or a ferroelectric semiconductor device of FIG. 2C taken along a line IV-IV′, and shown on an x-y plane. FIG. 2E is a view of a ferroelectric semiconductor device of FIG. 2B taken along a line V-V′ or a ferroelectric semiconductor device of FIG. 2C taken along a line VI-VI′, and shown on an x-y plane. FIG. 2F is a view of a ferroelectric semiconductor device of FIG. 2B taken along a line VII-VII′ or a ferroelectric semiconductor device of FIG. 2C taken along a line VIII-VIII′, and shown on an x-y plane.

Referring to FIGS. 2A to 2F, a ferroelectric memory device 1 may include first to eighth memory cell structures MCS1, MCS2, MCS3, MCS4, MCS5, MCS6, MCS7, and MCS8 disposed over a substrate 100. The first to eighth memory cell structures MCS1, MCS2, MCS3, MCS4, MCS5, MCS6, MCS7, and MCS8 may correspond to the first to eighth memory cells MC1, MC2, MC3, MC4, MC5, MC6, MC7, and MC8 of the ferroelectric semiconductor device S, respectively, shown in the circuit diagram of FIG. 1. In describing the ferroelectric semiconductor device 1 according to an embodiment of the present disclosure, sometimes a configuration of only one memory cell may be described for convenience of explanation.

The first to eighth memory cell structures MCS1, MCS2, MCS3, MCS4, MCS5, MCS6, MCS7, and MCS8 may have substantially the same configuration. Although not explicitly shown in FIGS. 2A to 2F, the eighth memory cell structure MCS8 may be disposed directly below the seventh memory cell structure MCS7, with both memory cell structures disposed over the substrate 100.

The first memory cell structure MCS1, the third memory cell structure MCS3, the fifth memory cell structure MCS5, and the seventh memory cell structure MCS7 may be disposed along first and second directions (e.g., the x-direction and the y-direction) parallel to a surface 100S of the substrate 100. Similarly, the second memory cell structure MCS2, the fourth memory cell structure MCS4, the sixth memory cell structure MCS6, and the eighth memory cell structure MCS8 may be disposed along the first and second directions (e.g., the x-direction and the y-direction) parallel to the surface 100S of the substrate 100.

The ferroelectric semiconductor device 1 may include the substrate 100, channel layers 138 disposed on the substrate 100 and extending in a third direction (i.e., the z-direction) substantially perpendicular to the surface 100S of the substrate 100, interfacial dielectric layers 136 disposed on the channel layers 138, floating electrode layers 134 disposed on the interfacial dielectric layers 136 and including first and second electrode portions 134a and 134b, ferroelectric layers 132 disposed on the first electrode portions 134a of the floating electrode layers 134, gate electrode layers 122 disposed on the ferroelectric layers 132, and insulation structures 141 covering the second electrode portions 134b of the floating electrode layers 134 over the substrate 100.

The first and second electrode portions 134a and 134b of the floating electrode layer 134 may be disposed on a plane substantially parallel to the surface 100S of the substrate 100. The first and second electrode portions 134a and 134b may contact different portions of the interfacial dielectric layer 136, respectively. The ferroelectric layer 132 may be disposed on the same plane and may contact the first electrode portion 134a while being spaced apart from the second electrode portion 134b. That is, the ferroelectric layer 132 may cover the first electrode portion 134a among the first and second electrode portions 134a and 134b of the floating electrode layer 134. The gate electrode layer 122 may be adjacent to the ferroelectric layer and disposed on the same plane. The insulation structure 141 may contact the second electrode portion 134b and be spaced apart from the first electrode portion 134a.

Referring to FIGS. 2B and 2C, the substrate 100 may include a semiconductor material. Specifically, the semiconductor material may include silicon (Si), germanium (Ge), gallium arsenide (GaAs), molybdenum sulfide (MoW₂), molybdenum selenide (MoSe₂), hafnium selenide (HfSe₂), indium selenide (InSe), gallium selenide (GaSe), black phosphorus, indium-gallium-zinc oxide (IGZO), or a combination of two or more thereof. The substrate 100 may be doped with an n-type dopant or a p-type dopant to have a predetermined conductivity.

Although not shown in FIGS. 2B and 2C, the substrate 100 may include integrated circuits. The integrated circuits may be circuits for driving and controlling at least one of the first to eighth memory cell structures MCS1, MCS2, MCS3, MCS4, MCS5, MCS6, MCS7, and MCS8. The integrated circuits may include, for example, devices such as diodes and transistors.

A source line insulation layer 110 may be disposed on the substrate 100. The source line insulation layer 110 may include an insulative material. The insulative material may include, for example, oxide, nitride, oxynitride, or a combination of two or more thereof. In some embodiments different from those shown in FIGS. 2B and 2C, at least one conductive layer may be disposed between the substrate 100 and the source line insulation layer 110. The conductive layer may function as an interconnection that connects different integrated circuits of the substrate 100 or an interconnection that connects the integrated circuit and a memory cell structure.

First hole patterns H1 penetrating the source line insulation layer 110 may be formed over the substrate 100. The first hole patterns H1 may be arranged in the first and second directions (e.g., the x-direction and the y-direction). Source line electrode layers 112 may be disposed on sidewall surfaces of the first hole patterns H1. The source line electrode layers 112 may be electrically connected to the integrated circuits of the substrate 100. The first hole patterns H1 in which the source line electrode layers 112 are formed may be filled with an insulative material to provide first filling layers 113. The insulative material may include, for example, oxide, nitride, oxynitride, or a combination of two or more thereof.

The source line electrode layer 112 may include a conductive material. The conductive material may include, for example, a doped semiconductor, metal, conductive metal nitride, conductive metal carbide, conductive metal silicide, or a conductive metal oxide. As another example, the conductive material may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIGS. 2B and 2C, gate structures 120 may be disposed on the source line insulation layer 110. Each of the gate structures 120 may include interlayer insulation layers 121 and gate electrode layers 122 that are alternately attacked in the third direction (e.g., the z-direction). The interlayer insulation layer 121 may include an insulative material. The insulative material may include, for example, oxide, nitride, oxynitride, or a combination of two or more thereof. The gate electrode layer 122 may include a conductive material. The conductive material may include, for example, a doped semiconductor, metal, conductive metal nitride, conductive metal carbide, conductive metal silicide, or a conductive metal oxide. As another example, the conductive material may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIGS. 2B, 2C, and 2D, second hole patterns H2 may be formed over the source line insulation layer 110 to penetrate the gate structures 120 and to expose the source line electrode layers 112 and the first filling layers 113. The second hole patterns H2 may be arranged in the first direction and second direction (e.g., the x-direction and y-direction).

The gate electrode layer 122 of the gate structure 120 may be recessed in a direction away from a central axis CX of the second hole pattern H2, for example, in the radial direction. The ferroelectric layer 132 and the floating electrode layer 134 may be disposed in at least a portion of a space formed by the recess. The gate electrode layer 122, the ferroelectric layer 132, and the floating electrode layer 134 may be disposed together on a plane parallel to the surface 100S of the substrate 100.

Referring to FIG. 2D, each of the floating electrode layers 134 may be disposed around a circumference of the second hole pattern H2. The ferroelectric layer 132 may be disposed between the gate electrode layer 122 and the floating electrode layer 134. The ferroelectric layer 132 may contact a portion of the floating electrode layer 134.

Meanwhile, each of the floating electrode layers 134 may include the first electrode portion 134a contacting the ferroelectric layer 132 and the second electrode portion 134b that does not contact the ferroelectric layer 132. The second electrode portion 134b may contact the insulation structure 141.

The ferroelectric layer 132 may include a ferroelectric material. The ferroelectric material may include, for example, hafnium oxide, zirconium oxide, hafnium zirconium oxide, or a combination of two or more thereof. The ferroelectric layer 132 may include a dopant injected therein. The dopant may include, for example, carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), gadolinium (Gd), lanthanum (La), or a combination thereof. The floating electrode layer 134 may include a conductive material. The conductive material may include, for example, a doped semiconductor, metal, conductive metal nitride, conductive metal carbide, conductive metal silicide, or a conductive metal oxide. As another example, the conductive material may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIGS. 2B to 2E, third hole patterns H3 may be formed on the source line insulation layer 110 to penetrate the gate structures 120. The third hole patterns H3 may be formed respectively around the same axis as that of the second hole patterns H2. A side wall surface of each of the third hole patterns H3 may expose the gate structure 120. In addition, the sidewall surface of each of the third hole patterns H3 may expose the second electrode portion 134b of the floating electrode layer 134 and the interlayer insulation layer 121. The third hole patterns H3 may be filled with an insulative material to provide the insulation structures 141 on the source line insulation layer 110. The insulative material may include, for example, oxide, nitride, oxynitride, or a combination of two or more thereof. Each of the insulation structures 141 may have a shape of a wall having a predetermined curvature to surround the second electrode portion 134b of the floating electrode layer 134.

Referring to FIG. 2D, the ferroelectric layer 132 may cover the first electrode portion 134a of the floating electrode layer 134 while having a first width w132. The ferroelectric layer 132 may be spaced apart from the second electrode portion 134b of the floating electrode layer 134. Each of the insulation structures 141 may cover the second electrode portion 134b of the floating electrode layer 134 while having a second width w141. The second width w141 may be greater than the first width w132. As an example, the second width w141 may be twice or more than the first width w132. As another example, the second width w141 may be five times or more than the first width w132. As another example, the second width w141 may be ten times or more than the first width w132.

Referring to FIGS. 2B, 2C, and 2D, the interfacial dielectric layer 136 may be disposed on the sidewall surface of each of the gate structures 120, exposed by the second hole patterns H2. The interfacial dielectric layer 136 may be disposed to cover the floating electrode layer 134 of each of the plurality of memory cell structures disposed along the third direction (i.e., the z-direction).

The interfacial dielectric layer 136 may include, for example, silicon oxide, silicon nitride, silicon oxynitride, aluminum oxide, hafnium oxide, zirconium oxide, or a combination of two or more thereof. The interfacial dielectric layer 136 may have an amorphous structure, for example. In an embodiment, the interfacial dielectric layer 136 may have a non-dielectric property. As an example, the interfacial dielectric layer 136 may have a paraelectric property.

The channel layer 138 may be disposed on a sidewall surface of the interfacial dielectric layer 136. The channel layer 138 may be electrically connected to the source line electrode layer 112. The channel layer 138 may include a semiconductor material. The semiconductor material may include, for example, doped silicon, doped germanium, doped gallium arsenide, and the like. The semiconductor material may include, for another example, a two-dimensional semiconductor material. The two-dimensional semiconductor material may include, for example, transition metal dichalcogenide (TMDC), black phosphorous, and the like. The transition metal dichalcogenide may include, for example, molybdenum selenide (MoSe₂), hafnium selenide (HfSe₂), indium selenide (InSe), gallium selenide (GaSe), and the like. As another example, the semiconductor material may include a conductive metal oxide. The conductive metal oxide may include indium oxide (In₂O₃), dopant-doped indium oxide (In₂O₃), indium gallium zinc oxide (InGaZnO₄), zinc oxide (ZnO), indium gallium oxide (InGaO₃), and the like. The dopant may include titanium (Ti), tungsten (W), silicon (Si), or a combination of two or more thereof.

In addition, the second hole patterns H2 in which the interfacial dielectric layer 136 and the channel layer 138 are disposed may be filled with an insulative material to provide insulating pillar structures 131. The insulative material may include, for example, oxide, nitride, oxynitride, or a combination of two or more thereof. In an embodiment, the insulating pillar structures 131 may extend in the third direction (i.e., the z-direction) over the substrate 100.

Referring to FIGS. 2B to 2E, channel layers 138 may be disposed on an outer circumferential surface of each of the insulating pillar structures 131. The interfacial dielectric layer 136 may be disposed around each of the insulating pillar structures 131 to surround the channel layer 138. In an embodiment, the first and second electrode portions 134a and 134b of the floating electrode layer 134 may be disposed to respectively contact different portions of the interfacial dielectric layer 136. The first and second electrode portions 134a and 134b of the floating electrode layer 134 may be electrically connected to each other.

In an embodiment, as shown in FIG. 2D, the ferroelectric layer 132 is disposed only on a sidewall surface of the first electrode portion 134a of the floating electrode layer 134. As a result, an interface between the floating electrode layer 134 and the ferroelectric layer 132 may be formed between the first electrode portion 134a of the floating electrode layer 134 and the ferroelectric layer 132. In other words, the interface area between the floating electrode layer 134 and the ferroelectric layer 132 may be reduced by the insulation structure 141, which prevents an interface between the second electrode portion 134b of the floating electrode layer 134 and the ferroelectric layer 132. As an example, the interface area between the first electrode portion 134a of the floating electrode layer 134 and the ferroelectric layer 132 may be smaller than an interface area between the interfacial dielectric layer 136 and the first and second electrode portions 134a and 134b of the floating electrode layer 134.

In an embodiment, the interface area between the floating electrode layer 134 and the ferroelectric layer 132 may be controlled by controlling a size of the first electrode portion 134a of the floating electrode layer 134. Accordingly, it is possible to change the ratio of the interface area between the floating electrode layer 134 and the ferroelectric layer 132 with respect to the interface area between the interfacial dielectric layer 136 and the floating electrode layer 134.

Referring to FIGS. 2C and 2D, a trench pattern TR may be disposed to penetrate the gate structures 120 on the source line insulation layer 110. The trench pattern TR may be formed to have a predetermined width w142 and to extend in the first direction (e.g., the x-direction). The trench pattern TR may be filled with an insulative material to provide a device isolation structure 142. The insulative material may include, for example, oxide, nitride, oxynitride, or a combination of two or more thereof. The device isolation structure 142 may isolate neighboring gate structures 120 from each other in the second direction (e.g., the y-direction), which is perpendicular to the first direction. As a result, the gate electrode layer 122 of each of the memory cell structures adjacent in the y-direction may be electrically separated from each other. As an example, as shown in FIG. 2D, the gate electrode layer 122 shared by the first and third memory cell structures MCS1 and MCS3 and the gate electrode layer 122 shared by the fifth and seventh memory cell structures MCS5 and MCS7 may be electrically separated by the device isolation structure 142. Meanwhile, the first and third memory cell structures MCS1 and MCS3 may share the gate electrode layer 122, so that the gate electrode layers 122 of the first and third memory cell structures MCS1 and MCS3 may maintain substantially the same electric potential. Similarly, the fifth and seventh memory cell structures MCS5 and MCS7 may share the gate electrode layer 122, so that the gate electrode layers 122 of the fifth and seventh memory cell structures MCS5 and MCS7 may maintain substantially the same electric potential.

Similarly, the gate electrode layers 122 of the second and fourth memory cell structures MCS2 and MCS4 and the gate electrode layers 122 of the sixth and eighth memory cell structures MCS6 and MCS8 may be electrically separated by the device isolation structure 142.

Referring to FIGS. 2A, 2B, and 2C, bit line insulation layer 151 including fourth hole patterns H4 may be disposed over the substrate 100. The bit line insulation layer 151 may cover upper surfaces of the gate structures 120, the insulation structures 141, the interfacial dielectric layer 136, the floating electrode layer 134, and the ferroelectric layer 132. The fourth hole patterns H4 may expose the insulating pillar structures 131 and the channel layer 138. The bit line insulation layer 151 may include an insulative material. The insulative material may include, for example, oxide, nitride, oxynitride, or a combination of two or more thereof.

A bit line electrode layer 162 may be disposed on a sidewall surface of each of the fourth hole patterns H4. The bit line electrode layer 162 may be electrically connected to the channel layer 138. The bit line electrode layer 162 may include a conductive material. The conductive material may include, for example, a doped semiconductor, metal, conductive metal nitride, conductive metal carbide, conductive metal silicide, or a conductive metal oxide. As another example, the conductive material may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof. In addition, each of the fourth hole patterns H4 in which the bit line electrode layer 162 is disposed may be filled with an insulative material to provide a second filling layer 163. The insulative material may include, for example, oxide, nitride, oxynitride, or a combination of two or more thereof.

In some embodiments, the first hole pattern H1 may be filled with the source line electrode layer 112 without the first filling layer 113. In some embodiments, the insulating pillar structure 131 might not be disposed inside the second hole patterns H2. That is, the interfacial dielectric layer 136 may be disposed on the sidewall surface of the gate structure 120 inside the second hole pattern H2, and the channel layer 138 may fill the second hole pattern H2 in which the interfacial dielectric layer 136 is formed. In some embodiments, the fourth hole patterns H4 may be filled with the bit line electrode layer 162 without the second filling layer 163.

Referring to FIGS. 2A to 2F, the ferroelectric memory device 1 may include the first to eighth memory cell structures MCS1, MCS2, MCS3, MCS4, MCS5, MCS6, MCS7, and MCS8 that are disposed over the substrate 100. The first and second memory cell structures MCS1 and MCS2 may be disposed to overlap with each other in the third direction (i.e., the z-direction) over the substrate 100. The first and second memory cell structures MCS1 and MCS2 may share the interfacial dielectric layer 136 and the channel layer 138. Similarly, the third and fourth memory cell structures MCS3 and MCS4 may be disposed to overlap with each other in the third direction (i.e., the z-direction) over the substrate 100, and share the interfacial dielectric layer 136 and the channel layer 138. The fifth and sixth memory cell structures MCS5 and MCS6 may be disposed to overlap with each other in the third direction (i.e., the z-direction) over the substrate 100, and share the interfacial dielectric layer 136 and the channel layer 138. The seventh and eighth memory cell structures MCS7 and MCS8 may be disposed to overlap with each other in the third direction (i.e., the z-direction) over the substrate 100, and share the interfacial dielectric layer 136 and the channel layer 138.

According to an embodiment of the present disclosure, in each of the first to eighth memory cell structures MCS1, MCS2, MCS3, MCS4, MCS5, MCS6, MCS7, and MCS8, the ferroelectric layer 132 may be disposed to cover the first electrode portion 134a among the first and second electrode portions 134a and 134b of the floating electrode layer 134, and the insulation structure 141 may be disposed to cover the second electrode portion 134b of the floating electrode layer 134. The interface area between the floating electrode layer 134 and the ferroelectric layer 132 may be reduced when the insulation structures 141 are present. As an example, the interface area between the first electrode portion 134a of the floating electrode layer 134 and the ferroelectric layer 132 may be smaller than the interface area between the interfacial dielectric layer 136 and the first and second electrode portions 134a and 134b of the floating electrode layer 134.

According to an embodiment of the present disclosure, by controlling the size of the first electrode portion 134a of the floating electrode layer 134, the interface area between the floating electrode layer 134 and the ferroelectric layer 132 can be controlled. Accordingly, the ratio of the interface area between the interfacial dielectric layer 136 and the floating electrode layer 134 with respect to the interface area between the floating electrode layer 134 and the ferroelectric layer 132 can also be controlled.

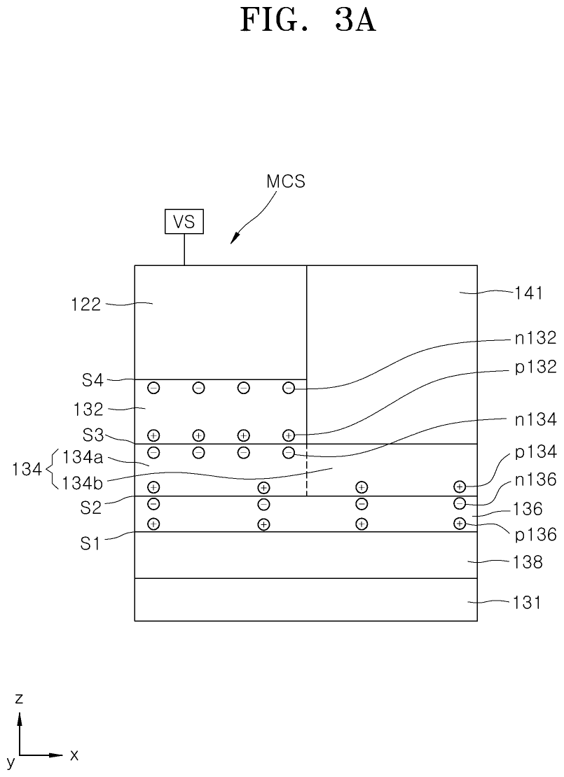

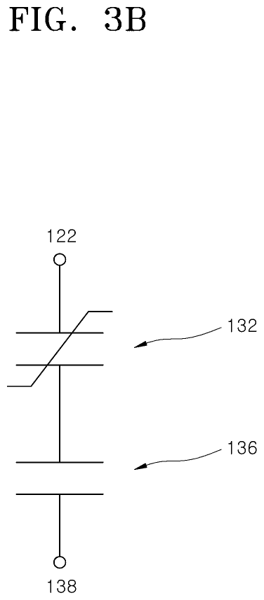

FIG. 3A is a view schematically illustrating an operation of a memory cell structure according to an embodiment of the present disclosure. FIG. 3B is a circuit diagram of a ferroelectric semiconductor device of FIG. 3A. In various embodiments, FIG. 3A may be a schematic diagram illustrating any one of the first memory cell structure MCS1, the third memory cell structure MCS3, the fifth memory cell structure MCS5, and the seventh memory cell structure MCS7 illustrated in FIG. 2D.

Referring to FIG. 3A, a memory cell structure MCS may include the channel layer 138 disposed on a sidewall surface of the insulating pillar structure 131, the interfacial dielectric layer 136 in contact with the channel layer 138, the floating electrode layer 134 (divided into the first and second electrode portions 134a and 134b) in contact with the interfacial dielectric layer 136, the ferroelectric layer 132 in contact with the first electrode portion 134a, and the gate electrode layer 122 in contact with the ferroelectric layer 132. In addition, the insulation structure 141 in contact the second electrode portion 134b of the floating electrode layer 134 is also illustrated.

A first interface S1 may be formed between the channel layer 138 and the interfacial dielectric layer 136, a second interface S2 may be formed between the interfacial dielectric layer 136 and the floating electrode layer 134, a third interface S3 may be formed between the floating electrode layer 134 and the ferroelectric layer 132, and a fourth interface S4 may be formed between the ferroelectric layer 132 and the gate electrode layer 122. In FIG. 3A, the third interface S3 may refer to an interface formed between the first electrode portion 134a of the floating electrode layer 134 and the ferroelectric layer 132. As shown in FIG. 3A, an interface area of the third interface S3 may be smaller than an interface area of the second interface S2.

Regarding the operation of the memory cell structure MCS, referring to FIG. 3A, a gate voltage VS having a positive polarity may be applied to the gate electrode layer 122 in a state in which the channel layer 138 is grounded. By applying the gate voltage VS, negative charges n132 may be induced inside the ferroelectric layer 132 adjacent to the fourth interface S4, and positive charges p132 may be induced inside the ferroelectric layer 132 adjacent to the third interface S3. Inside the first electrode portion 134a of the floating electrode layer 134 adjacent to the third interface S3, resulting negative charges n134 may cancel the positive charges p132 induced inside the ferroelectric layer 132. In addition, inside the floating electrode layer 134 adjacent to the second interface S2, positive charges p134 corresponding to the negative charges n134, which are induced in the region adjacent to the third interface S3, may be distributed. The positive charges p134 may be uniformly distributed along the second interface S2. In addition, negative charges n136 induced to offset the positive charges p134 may be distributed inside the interfacial dielectric layer 136 adjacent to the second interface S2, and positive charges p136 corresponding to the induced negative charges n136 may be distributed in the interfacial dielectric layer 136 adjacent to the first interface S1.

Although not shown, when a gate voltage VS having a negative polarity is applied to the gate electrode layer 122 in a state where the channel layer 138 is grounded, charges opposite in polarity to the charges shown in FIG. 3A may be induced in the regions adjacent to the first to fourth interfaces S1, S2, S3, and S4.

Referring to FIG. 3B, in the memory cell structure MCS, when a predetermined gate voltage Vg is applied between the channel layer 138 and the gate electrode layer 122, each of the ferroelectric layer 132 and the interfacial dielectric layer 136 may function as a dielectric layer of a capacitor. For convenience of explanation, the channel layer 138 is grounded, and the internal capacitance of the channel layer 138 may be omitted from the discussion. The capacitance of the ferroelectric layer 132 is indicated by C₁₃₂, and the capacitance of the interfacial dielectric layer 136 is indicated by C₁₃₆.

Referring to FIG. 3B, because the ferroelectric layer 132 and the interfacial dielectric layer 136 are electrically connected to each other in series, the total capacitance Cₜₒₜ of the series circuit may be calculated by Equation (1) below.

$$1 / {C}_{t o t} = 1 / {C}_{132} + 1 / {C}_{136} \qquad ( 1 )$$

C₁₃₂ and C₁₃₆ denote capacitances of the ferroelectric layer 132 and the interfacial dielectric layer 136, respectively.

The total charge Qₜₒₜ charged in the series circuit may be equal to the charge amount Q₁₃₂ charged in the ferroelectric layer 132 and the charge amount Q₁₃₆ charged in the interfacial dielectric layer 136 as shown in Equation (2) below.

$${Q}_{t o t} = {Q}_{132} = {Q}_{136} \qquad ( 2 )$$

From the Equation (2), the following equation (3) may be derived.

$${C}_{132} {V}_{132} = {C}_{136} {V}_{136} \qquad ( 3 )$$

Here, V₁₃₂ may mean a voltage distributed to the ferroelectric layer 132 from the gate voltage Vg, and V₁₃₆ may mean a voltage distributed to the interfacial dielectric layer 136 from the gate voltage Vg.

From the Equation (3), the following Equation (4) may be derived.

$${V}_{136} / {V}_{132} = {C}_{132} / {C}_{136} \qquad ( 4 )$$

From the Equation (4), as the capacitance C₁₃₂ of the ferroelectric layer 132 is increased compared to the capacitance C₁₃₆ of the interfacial dielectric layer 136, the voltage V₁₃₆ distributed to the interfacial dielectric layer 136 may be increased compared to the voltage V₁₃₂ distributed to the ferroelectric layer 132. Accordingly, as the voltage V₁₃₆ distributed to the interfacial dielectric layer 136 increases, the dielectric property of the interfacial dielectric layer 136 may deteriorate, and thus, the operational endurance of the memory cell structure MCS may deteriorate.

Conversely, as the capacitance C₁₃₂ of the ferroelectric layer 132 is decreased compared to the capacitance C₁₃₆ of the interfacial dielectric layer 136, the voltage V₁₃₆ distributed to the interfacial dielectric layer 136 may be decreased compared to the voltage V₁₃₂ distributed to the ferroelectric layer 132.

According to an embodiment of the present disclosure, by controlling the arrangement and disposition of the insulation structure 141, the interface area between the floating electrode layer 134 and the ferroelectric layer 132 may be increased or decreased compared to a case where the insulation structure 141 is omitted. As an example, in FIG. 3A the interface area at the third interface S3 between the ferroelectric layer 132 and the floating electrode layer 134 may be smaller than the interface area at the second interface S2 between the floating electrode layer 134 and the interfacial dielectric layer 136.

Because the capacitances of the ferroelectric layer 132 and the interfacial dielectric layer 136 are proportional to surface areas of the ferroelectric layer 132 and the interfacial dielectric layer 136 respectively in contact with the floating electrode layer 134, the capacitance C₁₃₂ of the ferroelectric layer 132 may be effectively decreased compared to the capacitance C₁₃₆ of the interfacial dielectric layer 136. As a result, in the memory cell structure MCS in which the ferroelectric layer 132 and the interfacial dielectric layer 136 are electrically connected in series, the operational endurance of the memory device can be effectively improved.

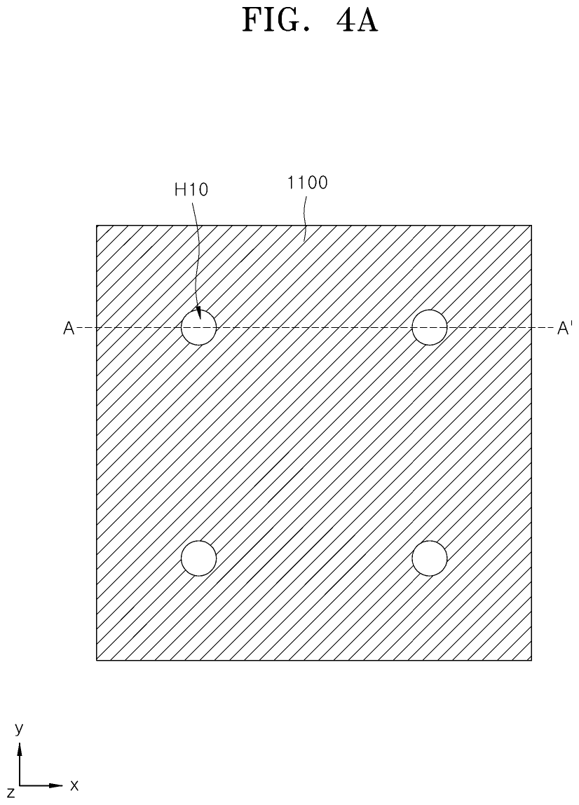

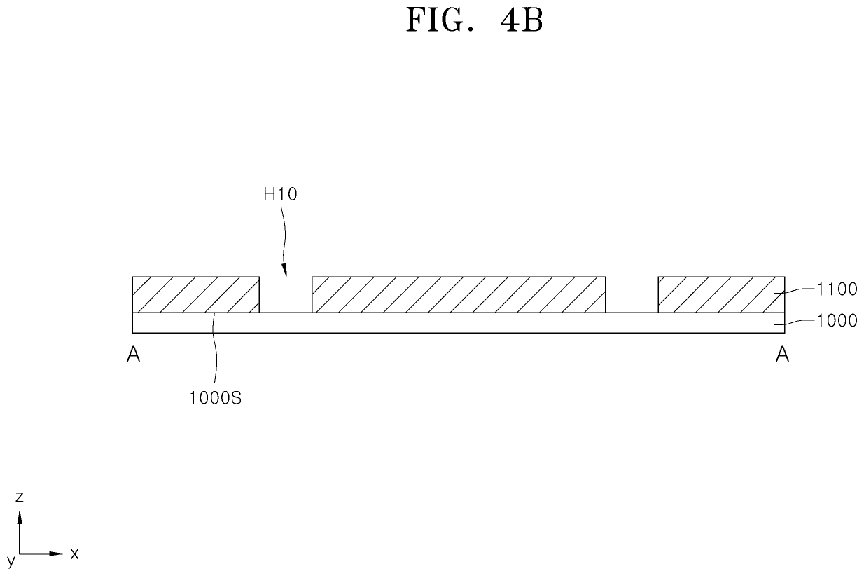

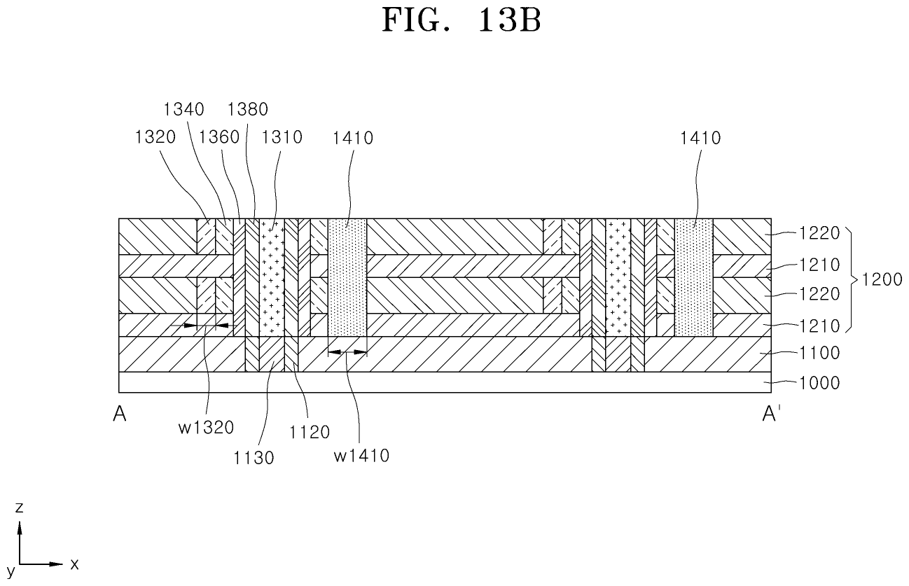

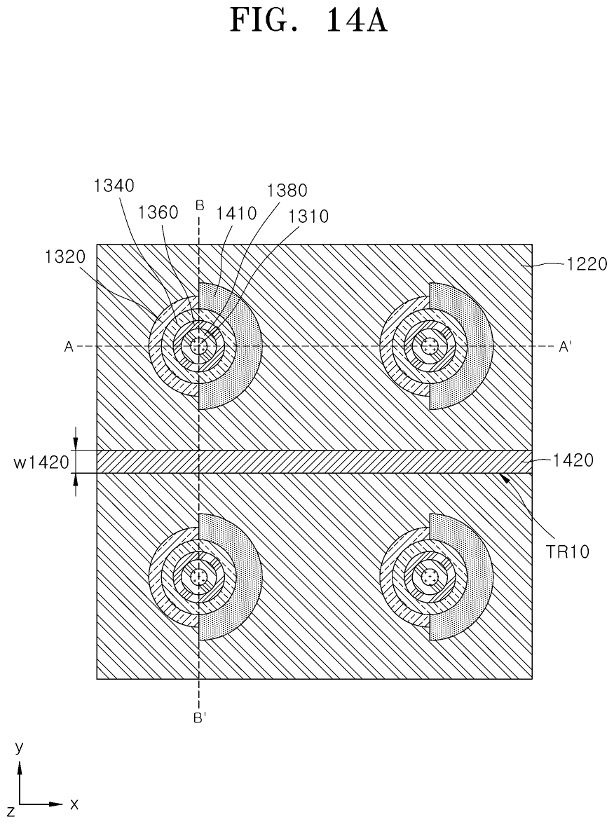

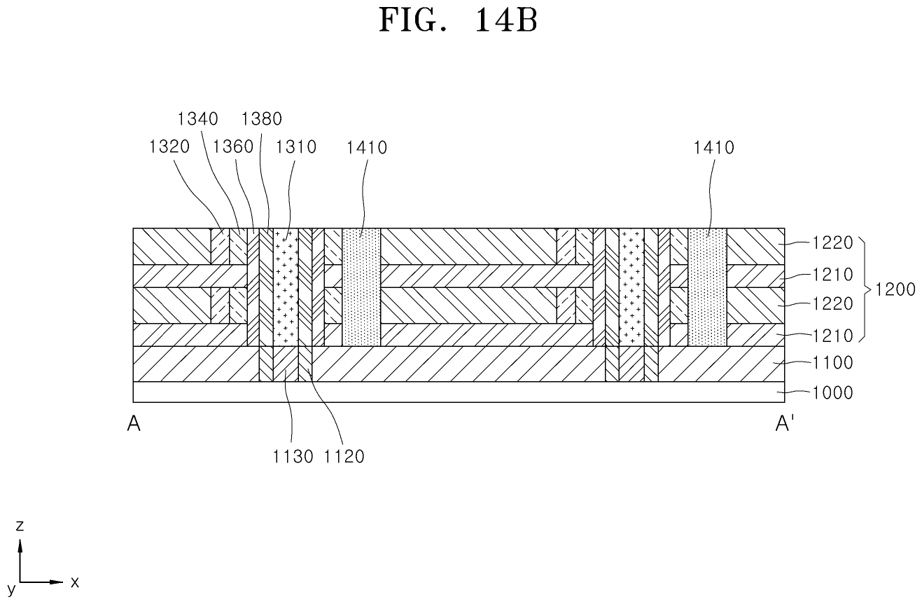

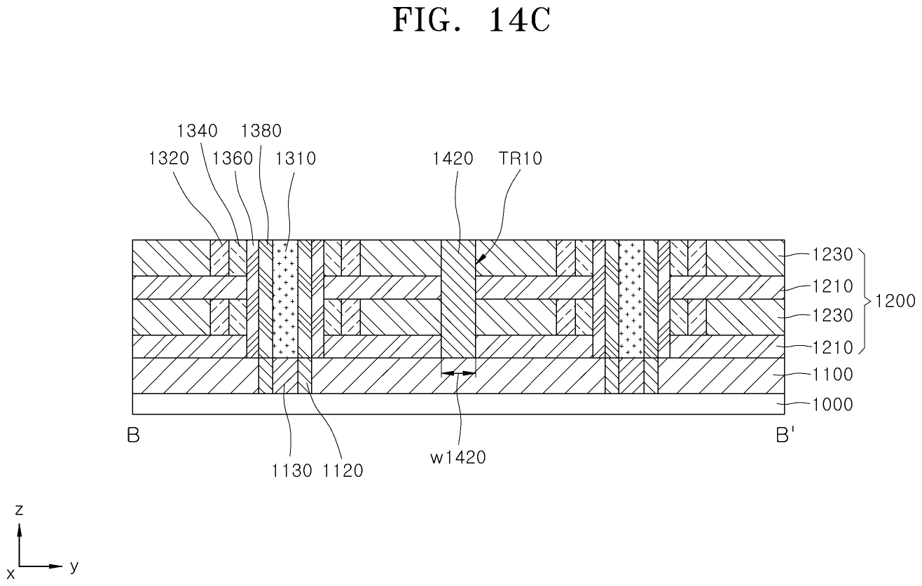

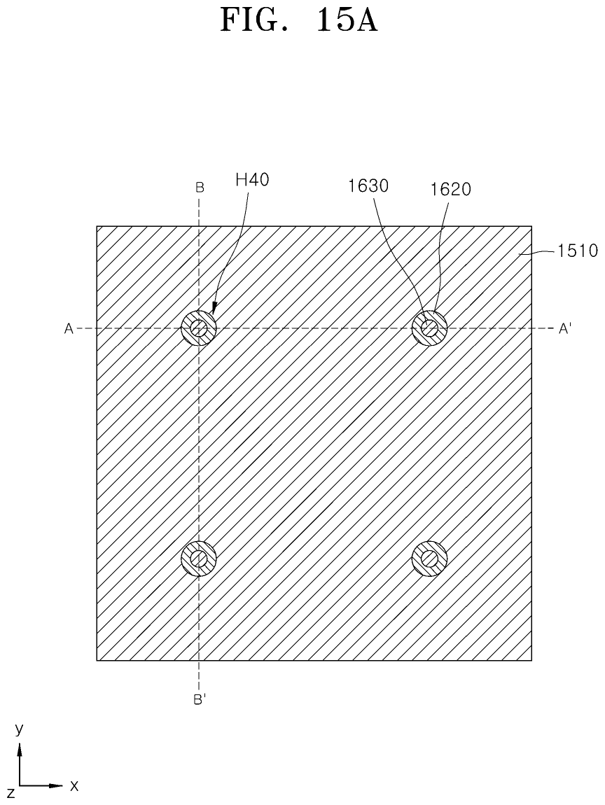

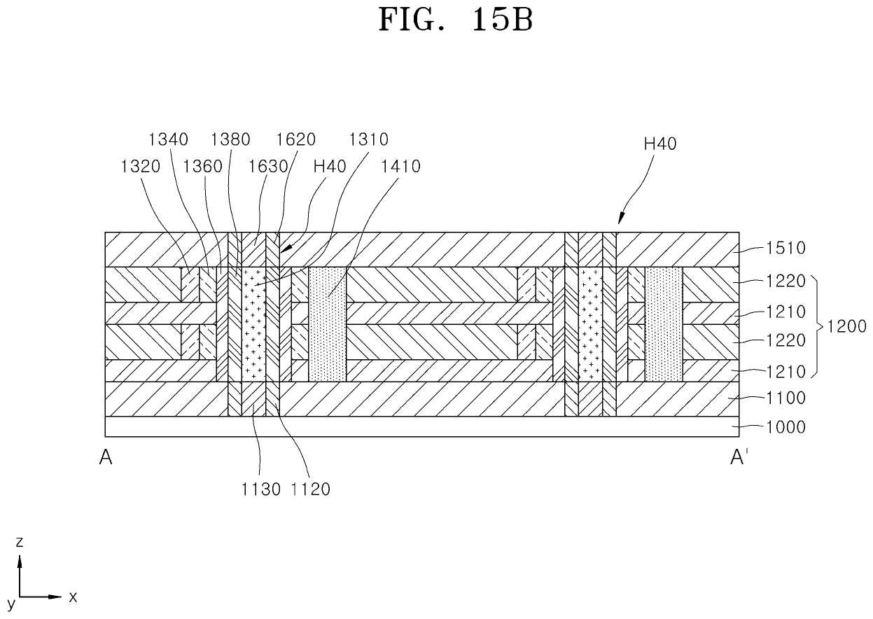

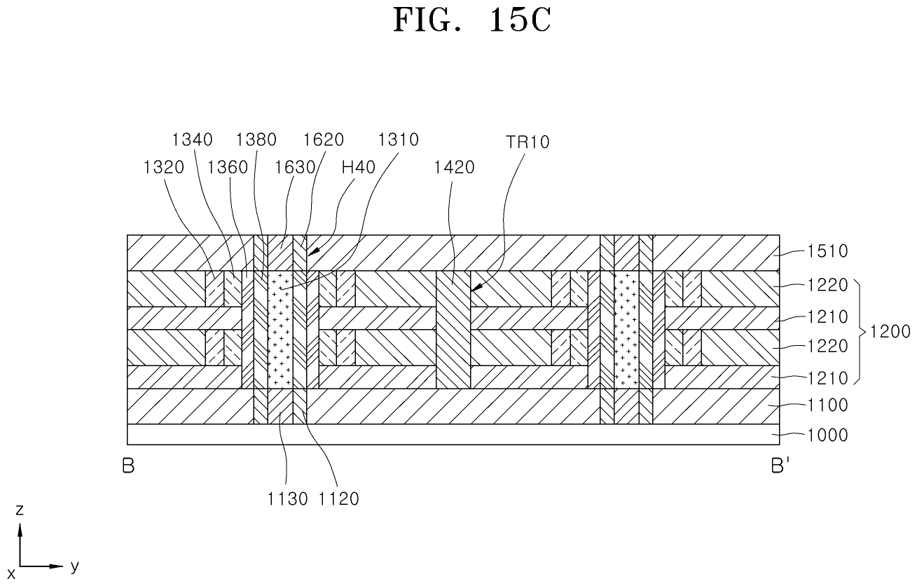

FIGS. 4A to 15A are plan views schematically illustrating a method of manufacturing a ferroelectric semiconductor device according to an embodiment of the present disclosure. FIGS. 4B to 15B are cross-sectional views corresponding to a semiconductor stack structure of FIGS. 4A to 15A taken along line A-A′. FIGS. 14C and 15C are cross-sectional views corresponding to a semiconductor stack structure of FIGS. 14A and 15A taken along line B-B′.

Referring to FIGS. 4A and 4B, a substrate 1000 may be provided. The substrate 1000 may include a semiconductor material. Specifically, the semiconductor material may include, for example, silicon (Si), germanium (Ge), gallium arsenide (GaAs), molybdenum sulfide (MoW₂), molybdenum selenide (MoSe₂), hafnium selenide (HfSe₂), indium selenide (InSe), gallium selenide (GaSe), black phosphorus, indium-gallium-zinc oxide (IGZO), or a combination of two or more thereof. The substrate 1000 may be doped with an n-type dopant or a p-type dopant to have a predetermined conductivity. The substrate 1000 may include integrated circuits. The integrated circuits may be circuits for driving and controlling memory cell structures to be formed over the substrate 1000. The integrated circuits may include, for example, elements such as diodes, transistors, and the like.

A source line insulation layer 1100 may be formed on the substrate 1000. The source line insulation layer 1100 may include an insulative material. The insulative material may include, for example, oxide, nitride, oxynitride, or a combination of two or more thereof. Next, first hole patterns H10 penetrating the source line insulation layer 1100 may be formed on the substrate 1000. The first hole patterns H10 may be arranged in the x-direction and y-direction parallel to a surface 1000S of the substrate 1000.

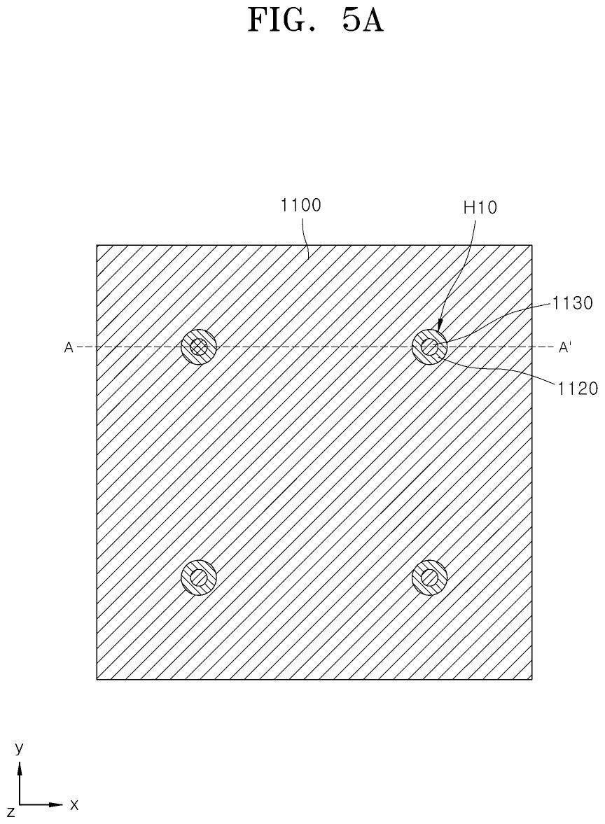

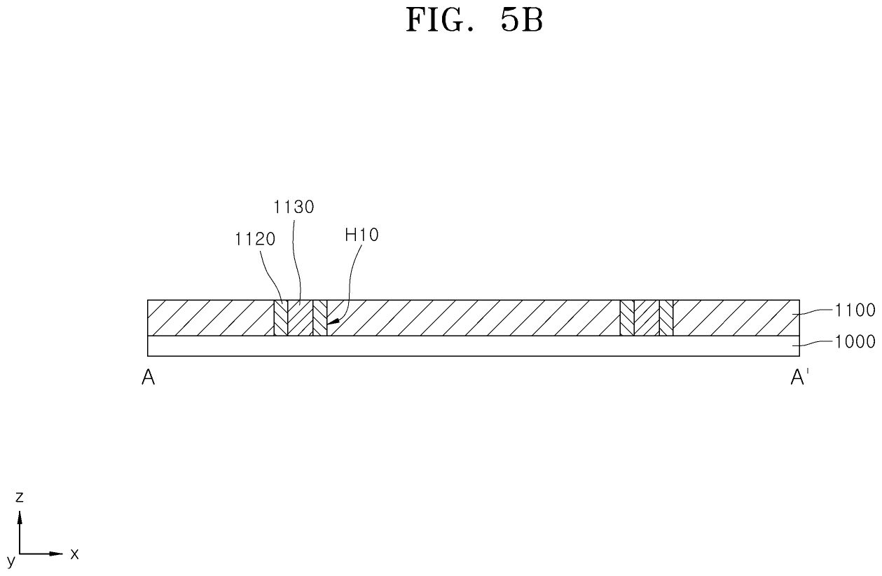

Referring to FIGS. 5A and 5B, a source line electrode layer 1120 may be formed on a sidewall surface of each of the first hole patterns H10. The source line electrode layer 1120 may be electrically connected to the integrated circuits of the substrate 1000. The source line electrode layer 1120 may include a conductive material. The conductive material may include, for example, doped semiconductor, metal, conductive metal nitride, conductive metal carbide, conductive metal silicide, or a conductive metal oxide. As another example, the conductive material may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof. Next, each of the first hole patterns H10 in which the source line electrode layer 1120 is formed may be filled with an insulative material to form a first filling layer 1130. The insulative material may include, for example, oxide, nitride, oxynitride, or a combination of two or more thereof.

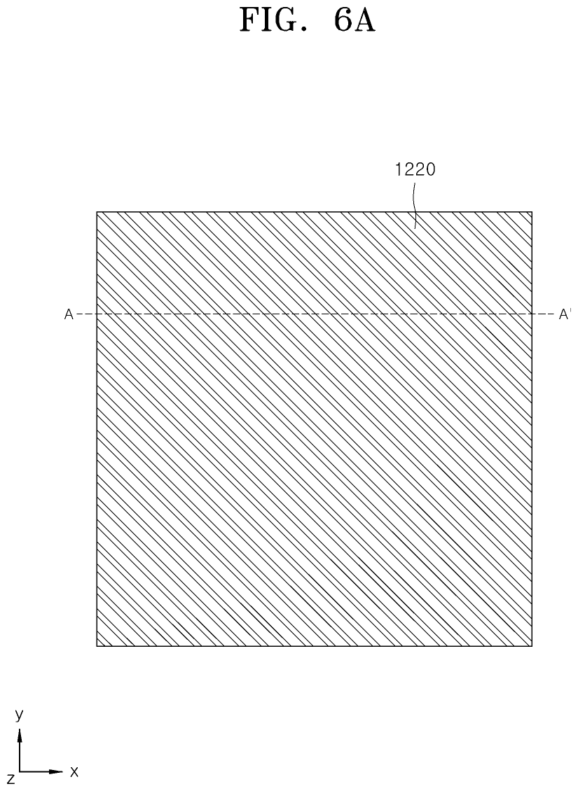

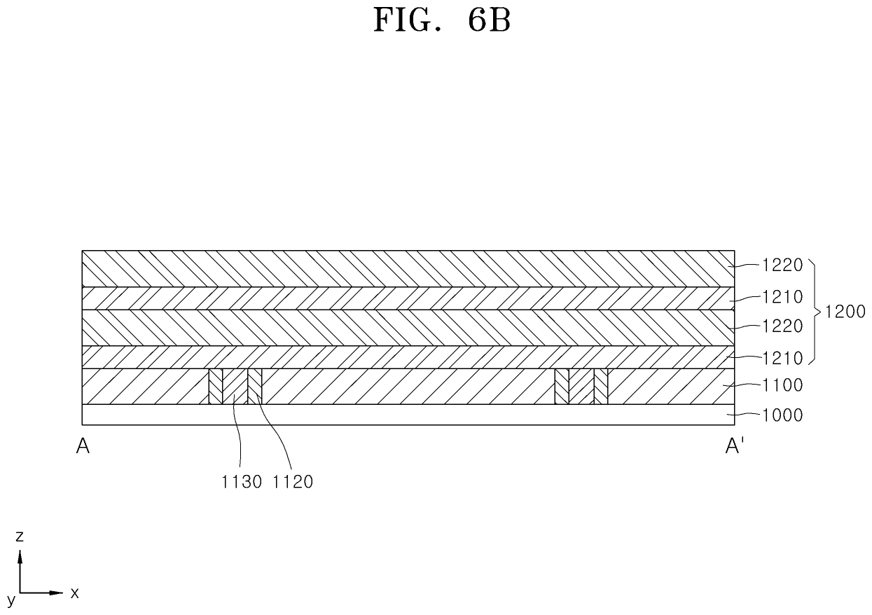

Referring to FIGS. 6A and 6B, a gate structure 1200 may be formed on the first filling layer 1130, the source line electrode layer 1120, and the source line insulation layer 1100. The gate structure 1200 may include interlayer insulation layers 1210 and gate electrode layers 1220 that are alternately stacked in the z-direction. The interlayer insulation layer 1210 may include an insulative material. The insulative material may include, for example, oxide, nitride, oxynitride, or a combination of two or more thereof. The gate electrode layer 1220 may include a conductive material. The conductive material may include, for example, a doped semiconductor, metal, conductive metal nitride, conductive metal carbide, conductive metal silicide, or a conductive metal oxide. As another example, the conductive material may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

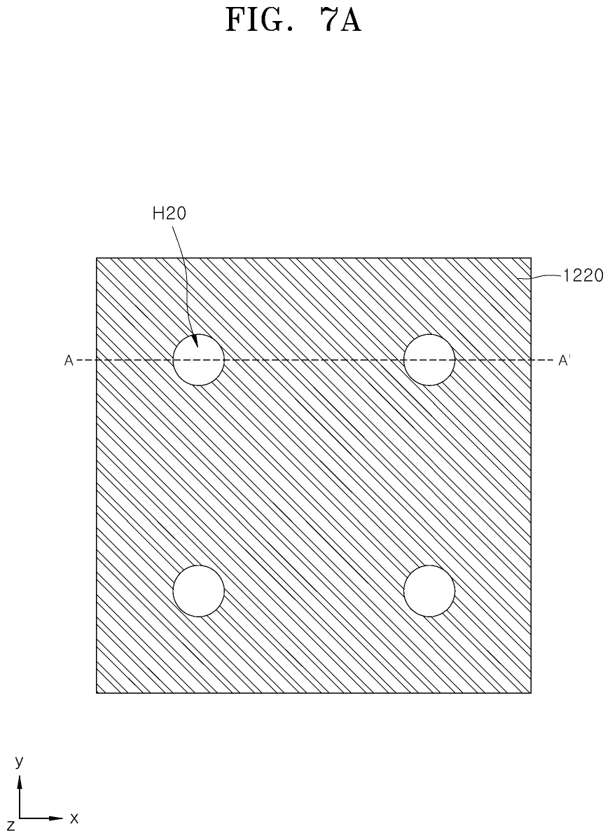

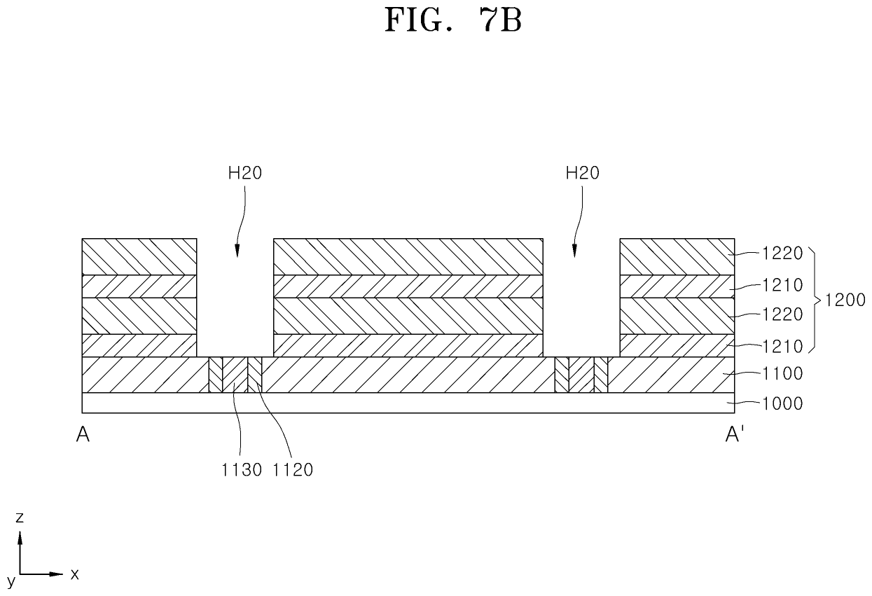

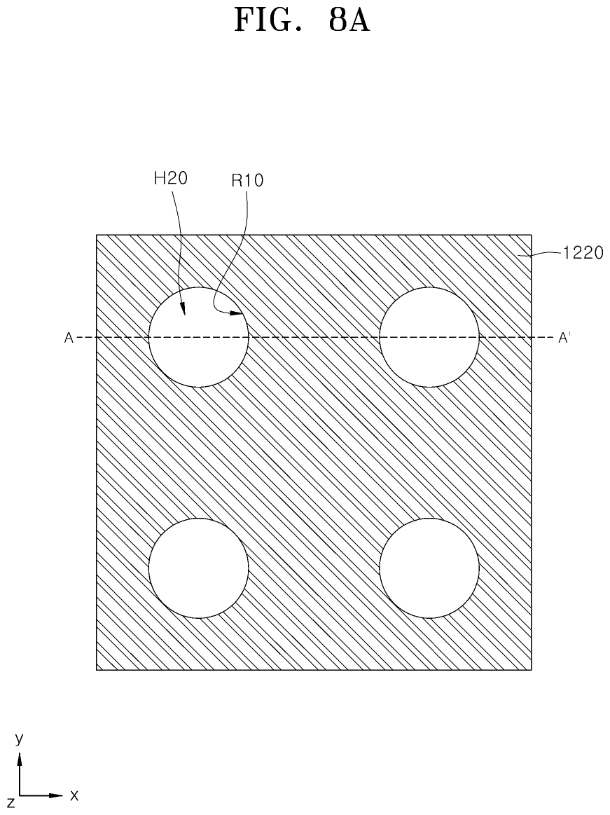

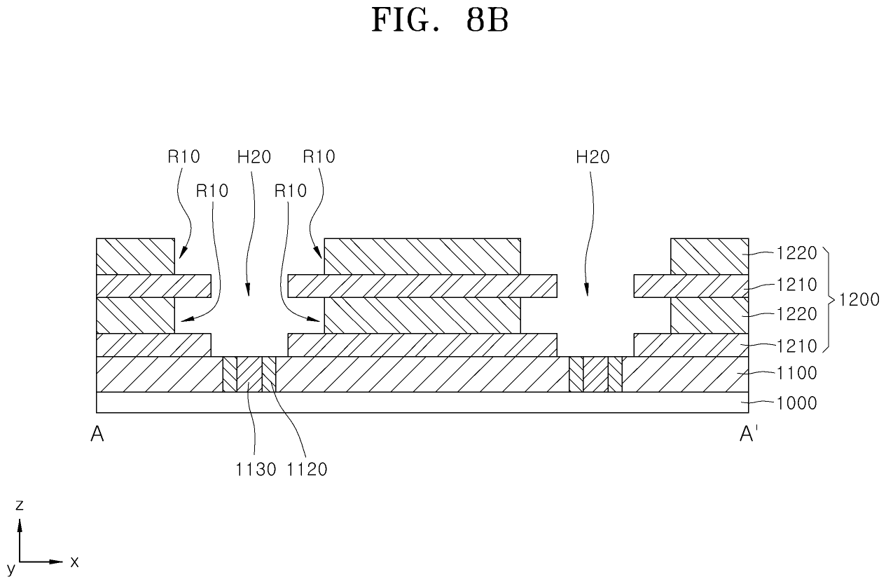

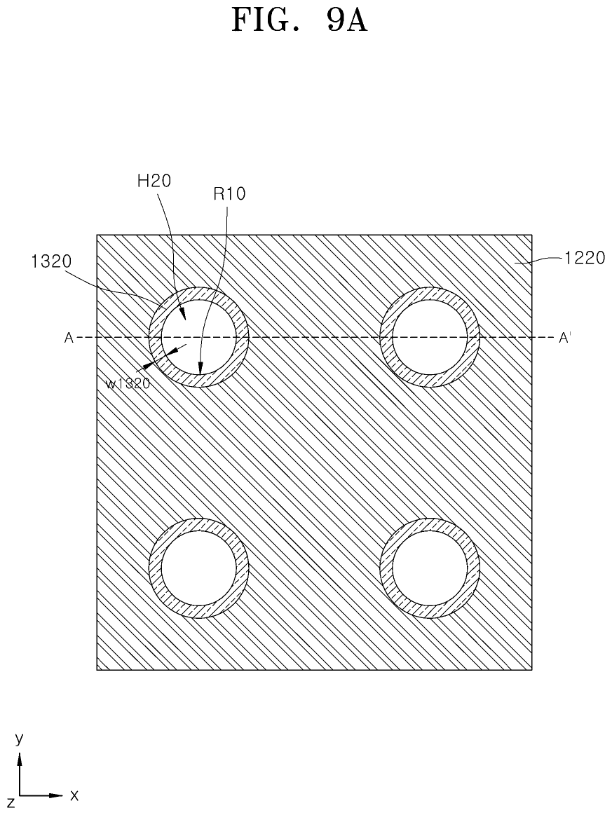

Referring to FIGS. 7A and 7B, second hole patterns H20 may be formed to penetrate the gate structure 1200 and expose the source line electrode layer 1120, the first filling layer 1130, and the source line insulation layer 1100. The second hole patterns H20 may be arranged in the x-direction and y-direction parallel to the surface 1000S of the substrate 1000.

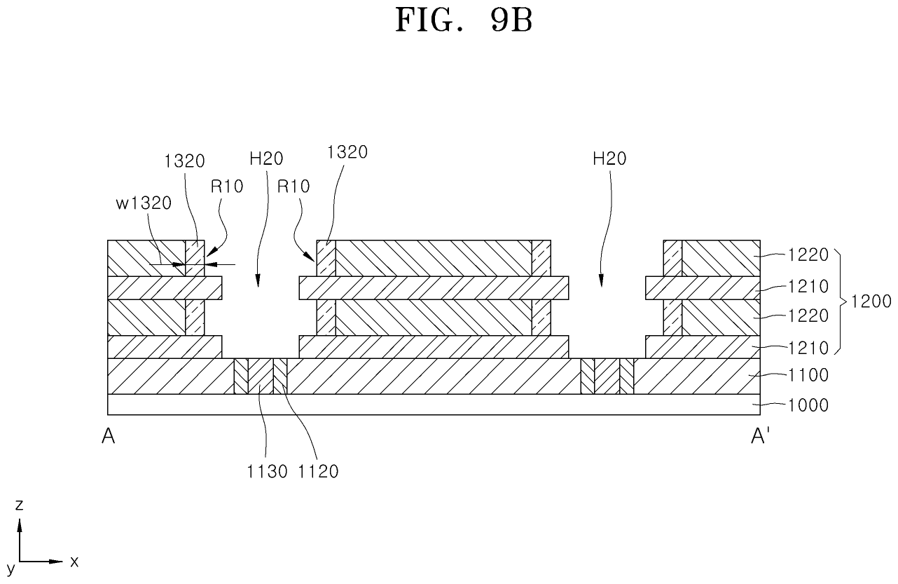

Referring to FIGS. 8A and 8B, edges of the gate electrode layers 1220 of the gate structure 1200 inside the second hole patterns H20 may be recessed to form first recess spaces R10. In an embodiment, the recess spaces R10 may be formed by forming an etch mask (not shown) exposing the second hole patterns H20 common to the gate structure 1200 and selectively etching the gate electrode layers 1220 with a wet etching method that takes advantage of etch selectivity between the gate electrode layer 1220 and the interlayer insulation layer 1210. After forming the recess spaces R10, the etch mask may be removed.

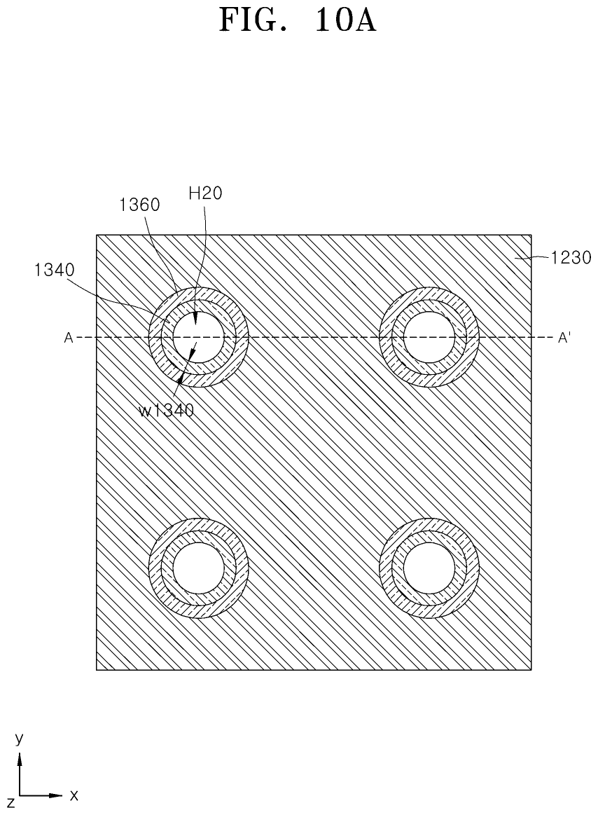

Referring to FIGS. 9A and 9B, a ferroelectric layer 1320 may be formed to fill portions of the first recess spaces R10 inside the second hole patterns H20. The ferroelectric layer 1320 may be formed in a shape of a ring having a predetermined width w1320. In an embodiment, the ferroelectric layer 1320 may be formed by filling the first recess spaces R10 with a ferroelectric material layer using an atomic layer deposition method and selectively etching the ferroelectric material layer using a wet etching method. The ferroelectric material layer may include, for example, hafnium oxide, zirconium oxide, hafnium zirconium oxide, or a combination of two or more thereof.

In an embodiment, when forming the ferroelectric material layer, a dopant may be injected. The dopant may include, for example, carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), gadolinium (Gd), lanthanum (La), or a combination thereof.

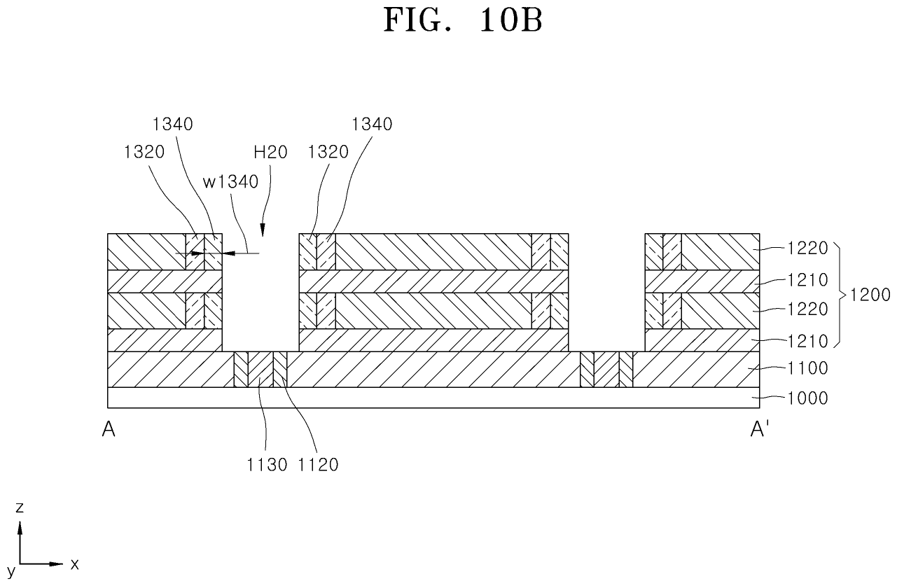

Referring to FIGS. 10A and 10B, after the ferroelectric layer 1320 is formed, the remaining portions of the first recess spaces R10 may be filled with a conductive material layer to form floating electrode layer 1340. In an embodiment, the conductive material layer may be formed using an atomic layer deposition method. The conductive material layer may include at least one selected from the above-described conductive materials. The floating electrode layer 1340 may be formed in a shape of a ring having a predetermined width w1340.

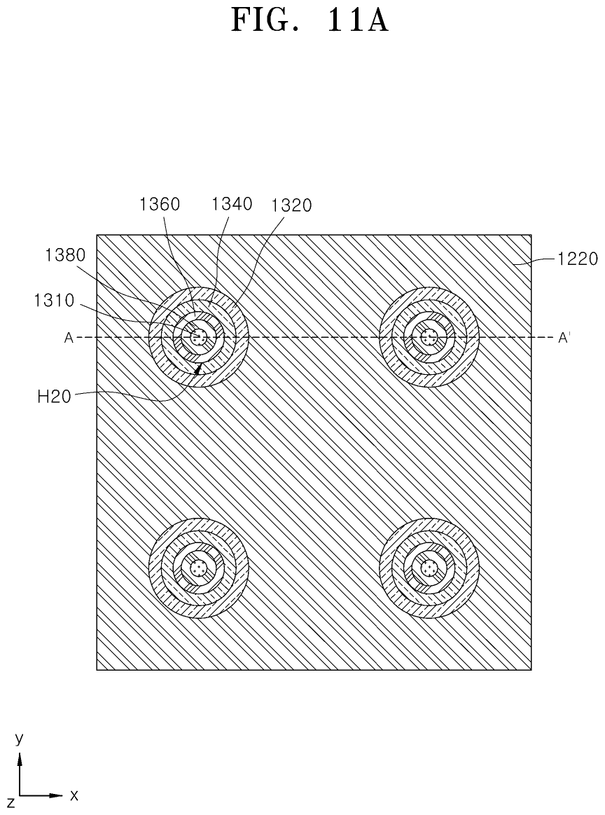

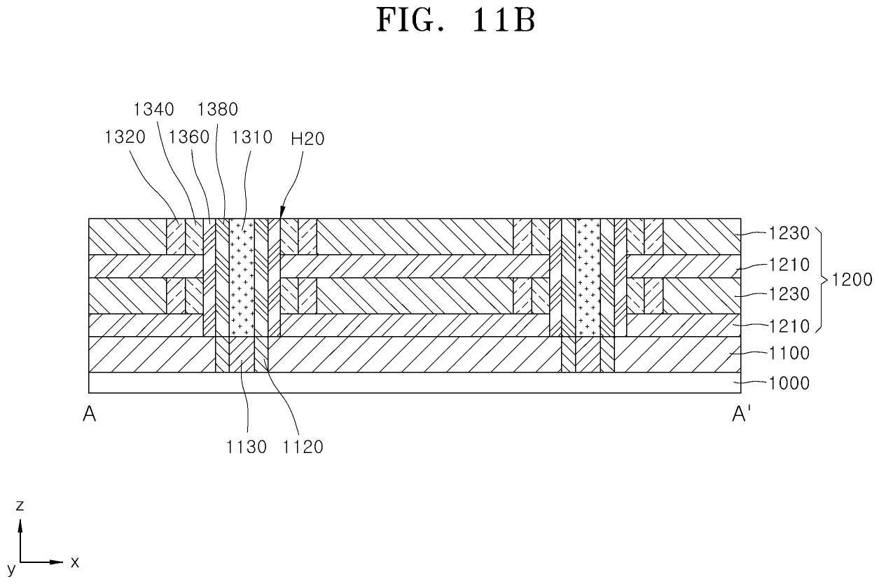

Referring to FIGS. 11A and 11B, an interfacial dielectric layer 1360 and a channel layer 1380 may be sequentially formed on the sidewall surface of each of the second hole patterns H20. The interfacial dielectric layer 1360 may include, for example, silicon oxide, silicon nitride, silicon oxynitride, aluminum oxide, hafnium oxide, zirconium oxide, or a combination of two or more thereof. As an example, the interfacial dielectric layer 1360 may have an amorphous structure. The channel layer 1380 may include a semiconductor material. The semiconductor material may include, for example, doped silicon, doped germanium, doped gallium arsenide, and the like. As another example, the semiconductor material may include a two-dimensional semiconductor material. The two-dimensional semiconductor material may include transition metal dichalcogenide (TMDC), black phosphorus, and the like. The transition metal dichalcogenide may include, for example, molybdenum selenide (MoSe₂), hafnium selenide (HfSe₂), indium selenide (InSe), gallium selenide (GaSe), and the like. As another example, the semiconductor material may include a conductive metal oxide. The conductive metal oxide may include indium oxide (In₂O₃), dopant-doped indium oxide (In₂O₃), indium gallium zinc oxide (InGaZnO₄), zinc oxide (ZnO), indium gallium oxide (InGaO₃), and the like. The dopant may include titanium (Ti), tungsten (W), silicon (Si), or a combination of two or more thereof.

The channel layer 1380 may be electrically connected to the source line electrode layer 1120. Each of the interfacial dielectric layer 1360 and the channel layer 1380 may be formed in a shape of a ring having a predetermined width. In an embodiment, the interfacial dielectric layer 1360 and the channel layer 1380 may be formed by an atomic layer deposition method.

Next, the second hole patterns H20 in which the interfacial dielectric layer 1360 and the channel layer 1380 are formed may be filled with an insulative material to form insulating pillar structures 1310 that contact the first filling layer 1130. The insulative material may include, for example, oxide, nitride, oxynitride, or a combination of two or more thereof.

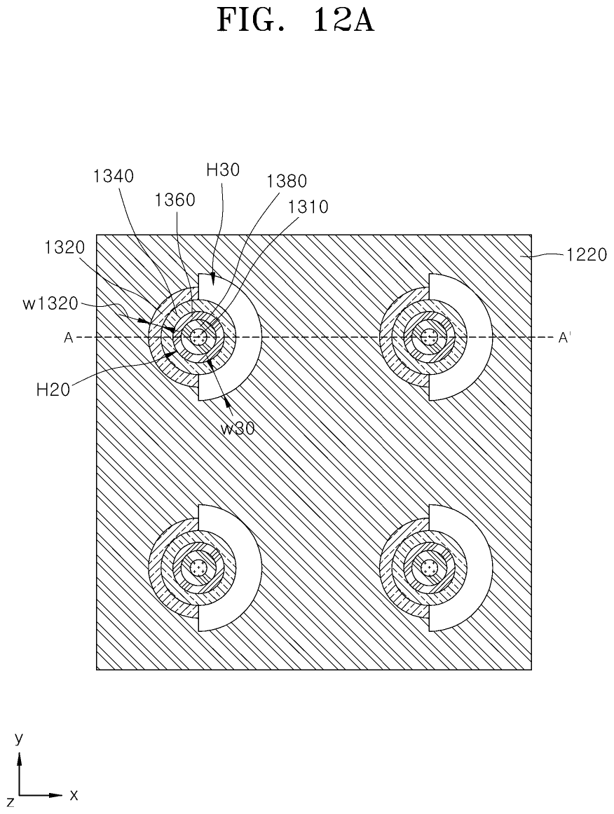

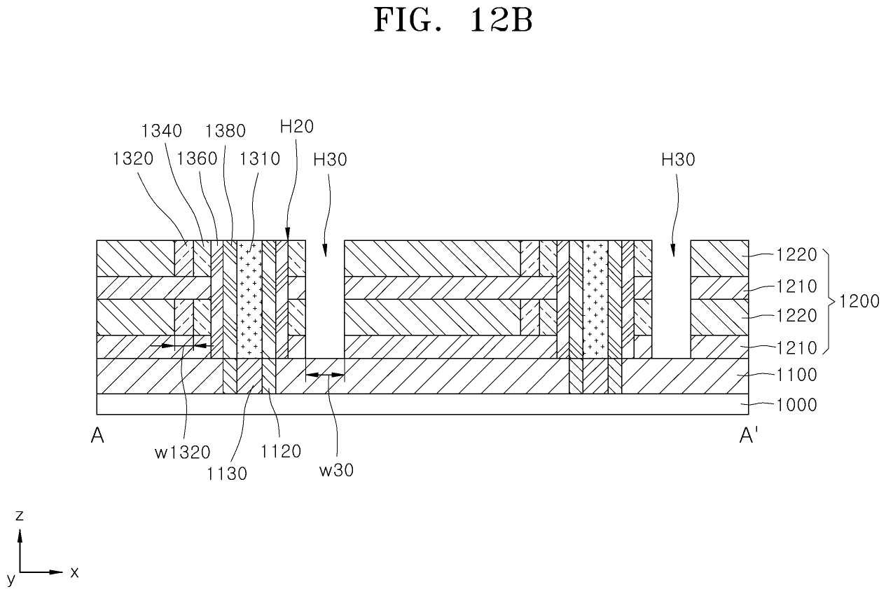

Referring to FIGS. 12A and 12B, third hole patterns H30 may be formed that penetrate the gate structure 1200 to expose the source line insulation layer 1100. The third hole patterns H30 may be formed to be adjacent to, but spaced apart from, sidewalls of the second hole patterns H20. A sidewall surface of each of the third hole patterns H30 may expose the gate structure 1200. In addition, a sidewall surface of each of the third hole patterns H30 may expose the floating electrode layers 1340 and adjacent interlayer insulation layers 1210. Each of the third hole patterns H30 may have a shape of a trench having a predetermined width w30. The width of the third hole pattern H30 may be greater than the width w1320 of the ferroelectric layer 1320. As an example, the width w30 of the third hole pattern H30 may be twice, or more than twice, the width w1320 of the ferroelectric layer 1320. As another example, the width w30 of the third hole pattern H30 may be five times, or more than five times, the width w1320 of the ferroelectric layer 1320. As another example, the width w30 of the third hole pattern H30 may be ten times, or more than ten times, the width w1320 of the ferroelectric layer 1320. The third hole patterns H30 may be arranged in the x-direction and y-direction parallel to the surface 1000S of the substrate 1000. In an embodiment, the hole pattern H30 is formed in the shape of a semi-circular trench, and a portion of the ferroelectric layer 1320 is removed by the hole pattern H30.

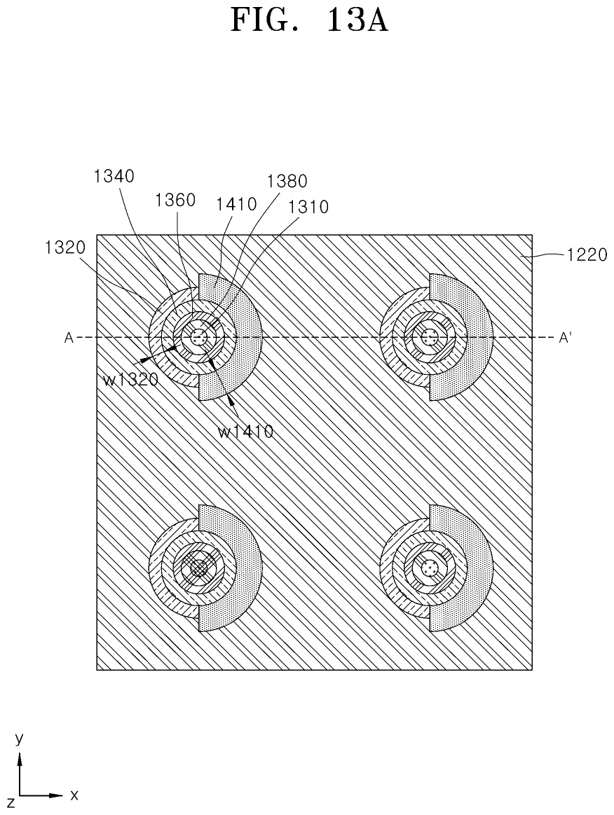

Referring to FIGS. 13A and 13B, the third hole patterns H30 may be filled with an insulative material to form insulation structures 1410 on the source line insulation layer 1100. Each of the insulation structures 1410 may have a shape of a wall having a predetermined curvature to surround a portion of the floating electrode layer 1340. Each of the insulation structures 1410 may have a predetermined width w1410. The width w1410 of the insulation structure 1410 may be greater than the width w1320 of the ferroelectric layer 1320. As an example, the width w1410 of the insulation structure 1410 may be twice, or greater than twice, the width w1320 of the ferroelectric layer 1320. As another example, the width w1410 of the insulation structure 1410 may be five times, or more than five times, the width w1320 of the ferroelectric layer 1320. As another example, the width w1410 of the insulation structure 1410 may be ten times, or more than ten times, the width w1320 of the ferroelectric layer 1320. In an embodiment, the insulation structure 1410 is formed in the shape of a semi-circular wall that takes the place of the portion of the ferroelectric layer 1320 removed by the hole pattern H30.

Referring to FIGS. 14A to 14C, a trench pattern TR10 may be formed to penetrate the gate structure 1200 to expose the source line insulation layer 1100. The trench pattern TR10 may be formed to have a predetermined width w1420 and to extend in one direction (e.g., the x-direction). Next, the trench pattern TR10 may be filled with an insulative material to form a device isolation structure 1420 on the source line insulation layer 1100. The insulative material may include, for example, oxide, nitride, oxynitride, or a combination of two or more thereof. The gate structure 1200 may be divided and the resulting structures separated from each other in a direction (e.g., the y-direction) perpendicular to the one direction by the device isolation structure 1420.

Referring to FIGS. 15A to 15C, bit line insulation layer 1510 may be formed on the structure of FIGS. 14A to 14C. The bit line insulation layer 1510 may include an insulative material. The insulative material may include, for example, oxide, nitride, oxynitride, or a combination of two or more thereof. Next, fourth hole patterns H40 are formed to penetrate the bit line insulation layer 1510 and expose the insulating pillar structures 1310 and the channel layer 1380.

Next, bit line electrode layer 1620 may be formed on a sidewall surface of each of the fourth hole patterns H40. The bit line electrode layer 1620 may be electrically connected to the channel layer 1380. The bit line electrode layer 1620 may include a conductive material. The conductive material may include, for example, a doped semiconductor, metal, conductive metal nitride, conductive metal carbide, conductive metal silicide, or a conductive metal oxide. As another example, the conductive material may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof. Next, each of the fourth hole patterns H40 in which the bit line electrode layer 1620 is formed may be filled with an insulative material to form a second filling layer 1630. The insulative material may include, for example, oxide, nitride, oxynitride, or a combination of two or more thereof. Through the above-described methods, a ferroelectric semiconductor device according to an embodiment of the present disclosure may be manufactured.

In some embodiments, the process of forming the first filling layer 1130 associated with FIGS. 5A and 5B may be omitted. Instead, the first hole patterns H10 may be filled with the source line electrode layer 1120 without the first filling layer 1130. In some embodiments, the process of forming the pillar structures 1310 associated with FIGS. 11A and 11B may be omitted. Instead, after the interfacial dielectric layer 1360 is formed on the sidewall surface of the gate structure 1200 inside each of the second hole patterns H20, the channel layer 1380 may fill the second hole patterns H20. In some embodiments, the process of forming the second filling layer 1630 associated with FIGS. 15A to 15C may be omitted. Instead, the fourth hole patterns H40 may be filled with the bit line electrode layer 1620 without the second filling layer 1630.

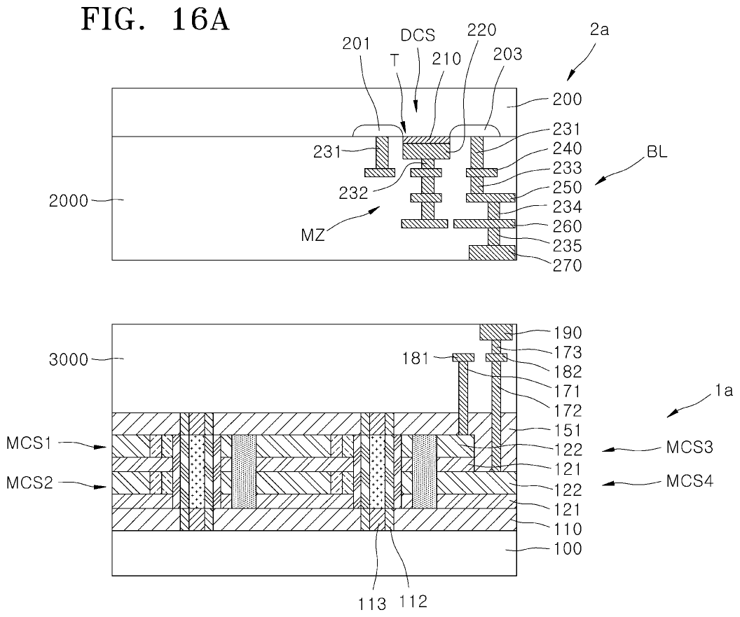

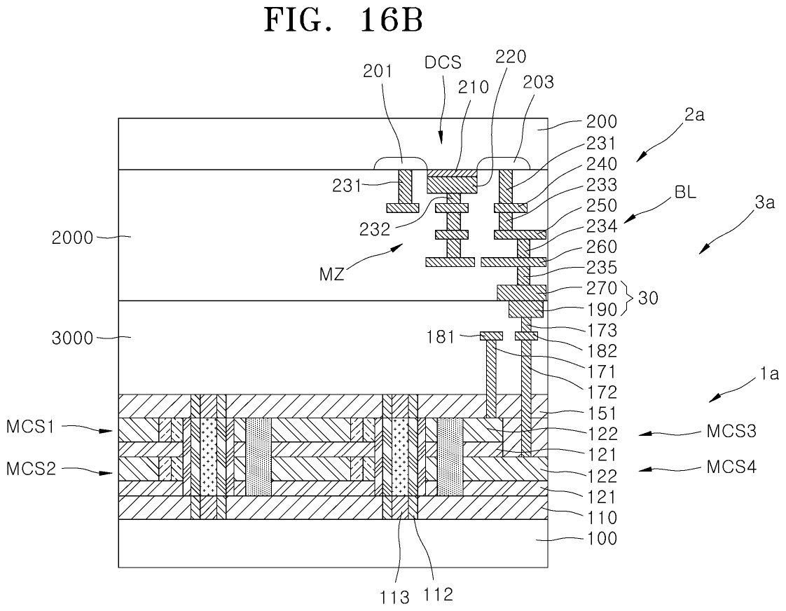

FIGS. 16A and 16B are cross-sectional views schematically illustrating a ferroelectric semiconductor device according to another embodiment of the present disclosure.

Referring to FIG. 16A, a first integrated circuit wafer 1a and a second integrated circuit wafer 2a may be prepared. The first integrated circuit wafer 1a may include a plurality of memory cell structures MCS1, MCS2, MCS3, and MCS4 disposed over a substrate 100. In an embodiment, the first integrated circuit wafer 1a may include a ferroelectric semiconductor device 1 described above with reference to FIGS. 2A to 2F.

The first integrated circuit wafer 1a may include a first via 171 extending from the gate electrode layer 122 of the first and third memory cell structures MCS1 and MCS3, and a first interconnection layer 181 connected to the first via 171. In addition, the first integrated circuit wafer 1a may include a second via 172 extending from the gate electrode layer 122 of the second and fourth memory cell structures MCS2 and MCS4, and a second interconnection layer 182 connected to the second via 172. In addition, the first integrated circuit wafer 1a may include a third via 173 electrically connected to the first and second interconnection layers 181 and 182, and a connection pad 190 electrically connected to the third via 173. In addition, the first integrated circuit wafer 1a may include an insulation layer 3000 covering the plurality of memory cell structures MCS1, MCS2, MCS3, and MCS4, the plurality of vias 171, 172, and 173, the plurality of interconnection layers 181 and 182, and portions of the connection pad 190 over the substrate 100.

The second integrated circuit wafer 2a may include an integrated circuit for driving and controlling the memory cell structures MCS1, MCS2, MCS3, and MCS4 of the first integrated circuit wafer 1a. The second integrated circuit wafer 2a may include an integrated circuit DCS disposed in a substrate 200, and interconnection portions MZ electrically connected to the integrated circuit DCS and integrated on the substrate 200. In addition, the second integrated circuit wafer 2a may include an insulation layer 2000 covering the integrated circuit DCS and the interconnection portions MZ on the substrate 200.

In an embodiment, the integrated circuit DCS may include a field effect transistor T. The field effect transistor T may include a gate insulation layer 210 and a gate electrode layer 220 disposed on the substrate 200, and a source region 201 and a drain region 203 disposed in the substrate 200.

The interconnection portion MZ may include, for example, a first contact layer 231 and a first interconnection layer 240 electrically connected to the source region 201. The interconnection portion MZ may include, for example, a second contact layer 232, the first interconnection layer 240, a first contact via 233, a second interconnection layer 250, a second contact via 234, and a third interconnection layer 260, which are electrically connected to the gate electrode layer 220. In addition, the interconnection portion MZ may include the first contact layer 231, the first interconnection layer 240, the first contact via 233, the second interconnection layer 250, the second contact via 234, the third interconnection layer 260, a third contact via 235, and a connection pad 270, which are electrically connected to the drain region 203. The interconnection portion electrically connected to the drain region 203 may constitute a bit line BL.

Referring to FIG. 16B, the first integrated circuit wafer 1a and the second integrated circuit wafer 2a may be bonded to each other to manufacture a device substrate 3a.

In the device substrate 3a, the connection pad 190 of the first integrated circuit wafer 1a and the connection pad 270 of the second integrated circuit wafer 2a may be bonded to each other to constitute a connection portion 30. As a result, the gate electrode layer 122 of each of the memory cell structures MCS1, MCS2, MCS3, and MCS4 of the first integrated circuit wafer 1a may be electrically connected to the bit line BL of the integrated circuit DCS of the second integrated circuit wafer 2a.

As described above, according to an embodiment of the present disclosure, after forming a first integrated circuit wafer having memory cell structures and a second integrated circuit wafer having an integrated circuit for driving and controlling the memory cell structures, the first and second integrated circuit wafers may be bonded to each other. Accordingly, a device substrate including a ferroelectric semiconductor device having the memory cell structures disclosed herein and an integrated circuit may be manufactured.

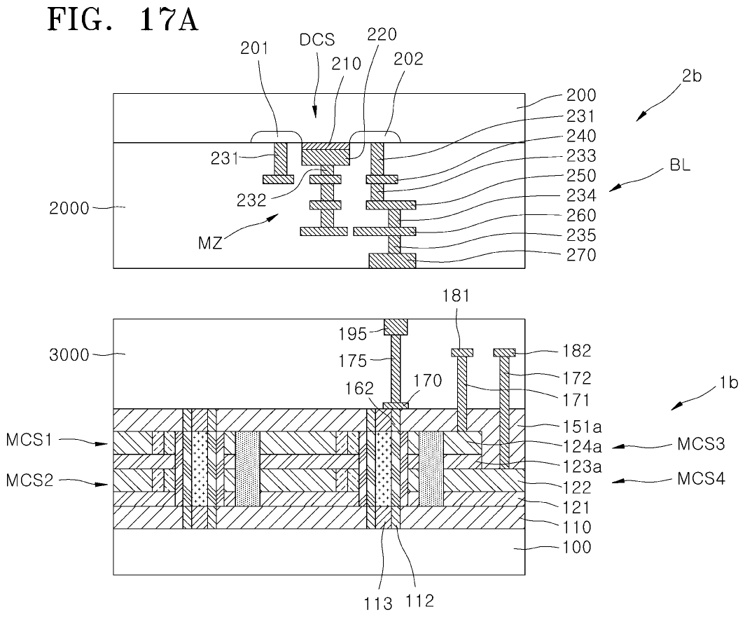

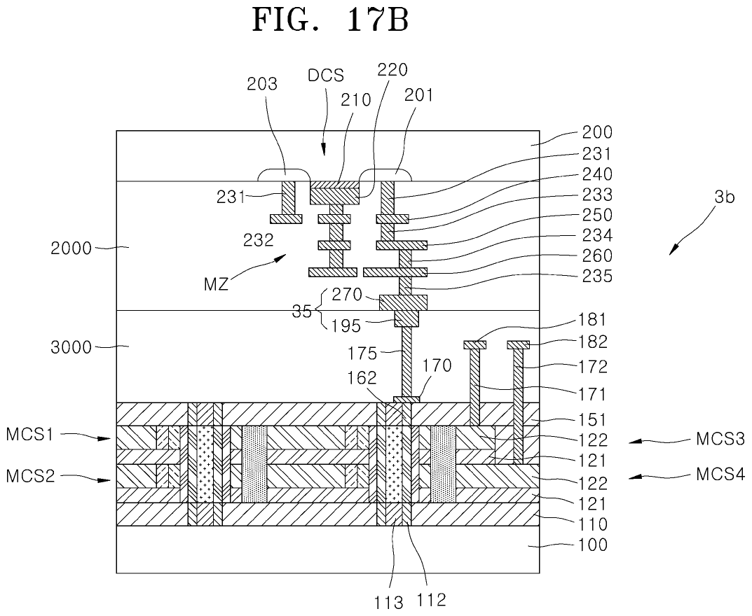

FIGS. 17A and 17B are cross-sectional views schematically illustrating a ferroelectric semiconductor device according to further another embodiment of the present disclosure.

Referring to FIG. 17A, a first integrated circuit wafer 1b and a second integrated circuit wafer 2b may be prepared. The first integrated circuit wafer 1b may include a structure in which a connection pad 195 may be electrically connected to a bit line electrode layer 162, compared to the first integrated circuit wafer 1a described above with reference to FIGS. 16A and 16B. The remainder of second integrated circuit wafer 2b may be substantially the same as the second integrated circuit wafer 2a described above with reference to FIGS. 16A and 16B.

In the first integrated circuit wafer 1b, a bit line interconnection layer 170 may be disposed on the bit line electrode layer 162. The bit line interconnection layer 170 may be electrically connected to the connection pad 195 through a bit line connection via 175.

Referring to FIG. 17B, the first integrated circuit wafer 1b and the second integrated circuit wafer 2b may be bonded to each other to manufacture a device substrate 3b. In the device substrate 3b, the connection pad 195 of the first integrated circuit wafer 1b and a connection pad 270 of the second integrated circuit wafer 2b may constitute a connection portion 35. As a result, the bit line electrode layer 162 of each of the memory cell structures MCS1, MCS2, MCS3, and MCS4 of the first integrated circuit wafer 1b may be electrically connected to the bit line BL of the integrated circuit DCS of the second integrated circuit wafer 2b.

As described above, according to an embodiment of the present disclosure, after a first integrated circuit wafer having memory cell structures and a second integrated circuit wafer including an integrated circuit for driving and controlling the memory cell structures are manufactured, the first and second integrated circuit wafers may be bonded to each other, thereby manufacturing a ferroelectric semiconductor device including the disclosed memory cell structures and an the integrated circuit.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A ferroelectric semiconductor device comprising:
a substrate;
a channel layer disposed over the substrate to extend in a vertical direction substantially perpendicular to a surface of the substrate;
an interfacial dielectric layer disposed on the channel layer;
a floating electrode layer disposed on the interfacial dielectric layer, the floating electrode layer including first and second electrode portions respectively disposed on different portions of the interfacial dielectric layer;
a ferroelectric layer disposed on the first electrode portion of the floating electrode layer;
a gate electrode layer disposed on the ferroelectric layer; and
an insulation structure covering the second electrode portion of the floating electrode layer over the substrate.

2. The ferroelectric semiconductor device of claim 1,
wherein the channel layer is disposed on an outer circumferential surface of a pillar structure extending in the vertical direction.

3. The ferroelectric semiconductor device of claim 2,
wherein the interfacial dielectric layer is disposed to surround the channel layer along the outer circumferential surface of the pillar structure, and
wherein the floating electrode layer is disposed to surround the interfacial dielectric layer along the outer circumferential surface of the pillar structure.

4. The ferroelectric semiconductor device of claim 1, wherein the first and second electrode portions of the floating electrode layer are electrically connected to each other.

5. The ferroelectric semiconductor device of claim 1, wherein the ferroelectric layer covers the first electrode portion among the first and second electrode portions of the floating electrode layer.

6. The ferroelectric semiconductor device of claim 1, further comprising:
a source line electrode layer disposed between one end portion of the channel layer and the substrate in the vertical direction; and
a bit line electrode layer disposed on the other end portion opposite to the one end portion of the channel layer.

7. The ferroelectric semiconductor device of claim 1, wherein the insulation structure is disposed to extend in the vertical direction to contact the second electrode portion of the floating electrode layer, the ferroelectric layer, and the gate electrode layer.

8. The ferroelectric semiconductor device of claim 1, wherein an interface area between the first electrode portion of the floating electrode layer and the ferroelectric layer is smaller than an interface area between the interfacial dielectric layer and the first and second electrode portions of the floating electrode layer.

9. A ferroelectric semiconductor device comprising:
a substrate;
a channel layer disposed over the substrate to extend in a vertical direction substantially perpendicular to a surface of the substrate;
an interfacial dielectric layer disposed on a sidewall surface of the channel layer along the vertical direction;
a plurality of floating electrode layers disposed over the substrate to be spaced apart from each other along the vertical direction, each of the floating electrode layers including first and second electrode portions disposed on a plane substantially parallel to the surface of the substrate;
a plurality of ferroelectric layers disposed to respectively contact the first electrode portions of the floating electrode layers;
a plurality of gate electrode layers disposed to be adjacent to the plurality of ferroelectric layers; and
an insulation structure covering the second electrode portions of each of the plurality of floating electrode layers over the substrate.

10. The ferroelectric semiconductor device of claim 9,
wherein the first and second electrode portions of each of the floating electrode layers are disposed to respectively contact different portions of the interfacial dielectric layer.

11. The ferroelectric semiconductor device of claim 10, wherein the channel layer is disposed on an outer circumferential surface of a pillar structure extending in the vertical direction.

12. The ferroelectric semiconductor device of claim 11,
wherein the interfacial dielectric layer is disposed to surround the channel layer along the outer circumferential surface of the pillar structure, and
wherein the plurality of floating electrode layers are disposed to surround the interfacial dielectric layer along the outer circumferential surface of the pillar structure.

13. The ferroelectric semiconductor device of claim 10, wherein a gate electrode layer, corresponding floating electrode layer, and corresponding ferroelectric layer are all disposed on the plane substantially parallel to the surface of the substrate.

14. The ferroelectric semiconductor device of claim 10, wherein each of the ferroelectric layers covers the first electrode portion among the first and second electrode portions of each of the plurality of floating electrode layers.

15. The ferroelectric semiconductor device of claim 10, further comprising:
a source line electrode layer disposed between one end portion of the channel layer and the substrate in the vertical direction; and
a bit line electrode layer disposed on the other end portion opposite to the one end portion of the channel layer.

16. The ferroelectric semiconductor device of claim 10, wherein the insulation structure is disposed to extend along the vertical direction, and contacts the second electrode portions of the plurality of floating electrode layers, the plurality of ferroelectric layers, and the plurality of gate electrode layers.

17. The ferroelectric semiconductor device of claim 10, wherein an interface area between the first electrode portion of each of the plurality of floating electrode layers and each of the ferroelectric layers is smaller than an interface area between the first and second electrode portions of each of the plurality of floating electrode layers and the interfacial dielectric layer.

18. A ferroelectric semiconductor device comprising:
a substrate; and
memory cell structures disposed along first and second directions that are substantially parallel to a surface of the substrate,
wherein each of the memory cell structures includes:
a channel layer disposed over the substrate to extend in a vertical direction substantially perpendicular to the surface of the substrate;
an interfacial dielectric layer disposed on the channel layer;
a floating electrode layer disposed on the interfacial dielectric layer, the floating electrode layer including first and second electrode portions respectively disposed on different portions of the interfacial dielectric layer;
a ferroelectric layer disposed on the first electrode portion of the floating electrode layer on a plane;
a gate electrode layer disposed on the ferroelectric layer; and
an insulation structure covering the second electrode portion of the floating electrode layer over the substrate.

19. The ferroelectric semiconductor device of claim 18, further comprising a device isolation structure disposed over the substrate to extend in the first direction and to separate neighboring memory cell structures in the second direction.

20. The ferroelectric semiconductor device of claim 18, wherein an interface area between the first electrode portion of the floating electrode layer and the ferroelectric layer is smaller than an interface area between the first and second electrode portions of the floating electrode layer and the interfacial dielectric layer.
